(19) United States
(12) Patent Application Publication
(10) Pub. No.: US 2025/0218912 A1
(43) Pub. Date: Jul. 3, 2025

(54) POLYMER HYBRID BONDING FOR COMPOSITE PACKAGES AND METHODS OF FORMING THE SAME

(71) Applicant: Taiwan Semiconductor Manufacturing Company Limited, Hsinchu (TW)

(72) Inventors: Tzuan-Horng Liu, Longtan Township (TW); An-Jhih Su, Taoyuan City (TW)

(21) Appl. No.: 18/402,773

(22) Filed: Jan. 3, 2024

(51) Int. Cl. H01L 23/498; H01L 21/48; H01L 23/00; H01L 23/31; H01L 25/10

(52) U.S. Cl. CPC H01L 23/49811; H01L 21/481; H01L 23/3185; H01L 23/49822; H01L 24/08; H01L 25/105; H01L 2224/08235; H01L 2924/15172; H01L 2924/1533

(57) ABSTRACT

A bonded assembly includes a first package structure including first metallic bump structures and a first polymer bonding layer laterally surrounding the first metallic bump structures; a second package structure including second metallic bump structures and a second polymer bonding layer laterally surrounding the second metallic bump structures; and solder material portions located between the first metallic bump structures and the second metallic bump structures. Each of the solder material portions is bonded to a respective one of the first metallic bump structures and a respective one of the second metallic bump structures, and the second polymer bonding layer is bonded to the first polymer bonding layer through polymer-to-polymer bonding.

### BACKGROUND

Advanced semiconductor packaging requires cost-effective and efficient high-density metallic bonding structure that may provide high mechanical strength and reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an exemplary structure after attaching a semiconductor die and a dummy die to a first carrier wafer according to an embodiment of the present disclosure.

FIG. 2 is a vertical cross-sectional view of the exemplary structure after formation of a first molding compound frame according to an embodiment of the present disclosure.

FIG. 3 is a vertical cross-sectional view of the exemplary structure after formation of a first-stage composite semiconductor package and attachment of through-interposer via structures according to an embodiment of the present disclosure.

FIG. 4 is a vertical cross-sectional view of the exemplary structure after attaching a first semiconductor substrate containing proximal metallic bump structures and a proximal polymer bonding layer to the first-stage composite semiconductor package according to an embodiment of the present disclosure.

FIGS. 5A-5I illustrate sequential vertical cross-sectional views of exemplary package structures that may be bonded using a hybrid bonding process of the present disclosure.

FIG. 6 is a vertical cross-sectional view of the exemplary structure after formation of a molding compound interposer matrix according to an embodiment of the present disclosure.

FIG. 7 is a vertical cross-sectional view of the exemplary structure after formation of second redistribution wiring interconnects, second redistribution dielectric layers, distal metallic bump structures, and a distal polymer bonding layer according to an embodiment of the present disclosure.

FIG. 8 is a vertical cross-sectional view of the exemplary structure after attaching a second carrier wafer and detaching the first carrier wafer according to an embodiment of the present disclosure.

FIG. 9 is a vertical cross-sectional view of the exemplary structure after detaching the second carrier wafer and singulating a reconstituted wafer including an array of second-stage composite packages into discrete composite packages according to an embodiment of the present disclosure.

FIG. 10 is a vertical cross-sectional view of an in-process semiconductor interposer within a wafer including an array of in-process semiconductor interposers according to an embodiment of the present disclosure.

FIG. 11 is a vertical cross-sectional view of an assembly including an in-process semiconductor interposer, a composite package, and two high bandwidth memory dies within a unit area of the wafer according to an embodiment of the present disclosure.

FIG. 12 is a vertical cross-sectional view of the assembly after formation of molding compound multi-die frame according to an embodiment of the present disclosure.

FIG. 13 is a vertical cross-sectional view of the assembly after thinning the backside of the wafer and after dicing a reconstituted wafer into third-stage composite packages according to an embodiment of the present disclosure.

FIG. 14 is a vertical cross-sectional view of a first assembly of a third-stage composite package and a packaging substrate according to an embodiment of the present disclosure.

FIG. 15 is a vertical cross-sectional view of a second assembly of a third-stage composite package and a packaging substrate according to an embodiment of the present disclosure.

FIG. 16 is a vertical cross-sectional view of a third assembly of a third-stage composite package and a packaging substrate according to an embodiment of the present disclosure.

FIG. 17 is a flowchart illustrating steps for forming a bonded assembly according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Ordinals such as “first,” “second,” “third,” etc. are generally not a part of a noun that refers to an element, but are merely adjectives. As such, same elements may be referred to with different ordinals across the specification and the claims. Further, whenever multiple elements and/or similar elements are present, such multiple elements and/or similar elements may be numbered in any order. Thus, the possibility of numbering elements with different ordinals are expressly contemplated for each case in which a plurality of elements is present. Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments disclosed herein are directed to semiconductor devices, and particularly to a chip-on-wafer-on-board (CoWoB) structure using spacer dies and methods for forming the same. A chip-on-wafer-on-substrate (CoWoS®) structures use a fan-out package including a chip-on-wafer structure that is bonded to a packaging substrate. Thus, a packaging substrate functions as an intermediary structure between the fan-out package (which is a chip-on-wafer structure) and a printed circuit board. However, the manufacture of a packaging substrate may be costly, and die warpage during attachment to the packaging substrate may be a yield detractor.

According to an aspect of the present disclosure, metallic bump structures that are compatible with polymer bonding layers are used to provide bonding between stacked package structures. Mating pairs of metallic bump structures are bonded using intermediate solder material portions. A pair of polymer bonding layers are bonded to each other around an array of solder material portion to provide polymer-to-polymer bonding in addition to a solder-mediated bonding. The hybrid bonding method of the present disclosure may be used to provide cost-effective and efficient bonding between packaging structures using high-density bump structures that provide strong and rigid bonding. In addition, the polymer-to-polymer bonding provides extra bonding strength. Various embodiments of the present disclosure may be used to provide highly reliable bonding in package structures for high-performance mobile devices, which may comprise various types of processors such as accelerated processing units, central processing units, graphic processing units, and field programmable gate arrays, and/or may comprise various memory dies. Various aspects of embodiments of the present disclosure are now described with reference to accompanying figures.

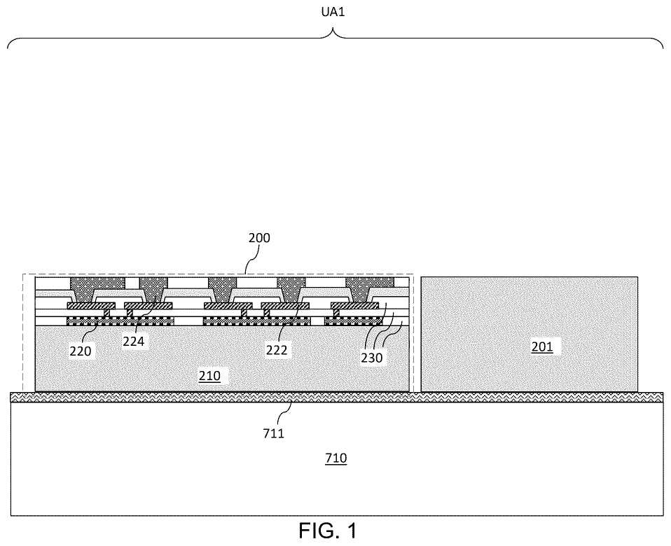

Referring to FIG. 1, an exemplary structure according to an embodiment of the present disclosure is illustrated. The exemplary structure comprises a semiconductor die 200 and an optional dummy die 201 that are attached to a top side of a first carrier wafer 710. The first carrier wafer 710 may comprise a transparent wafer such as a glass wafer. The first carrier wafer 710 may comprise a two-dimensional array of unit areas UA1 such as a rectangular array of unit areas UA1. In this embodiment, multiple instances of a unit area UA1 may be repeated along a first horizontal direction with a first pitch, and along a second horizontal direction with a second pitch. The illustrated portion of the exemplary structure corresponds to a region of a single unit area UA1. Generally, a set of at least one semiconductor die 200 and optionally at least one dummy die 201 may be attached to the first carrier wafer 710 within each unit area UA1. In one embodiment, a first die attachment film (DAF) 711 may be applied to the top surface of the first carrier wafer 710, and each set of at least one semiconductor die 200 and optionally at least one dummy die 201 may be attached to the first DAF 711 by performing a pick-and-place operation.

Generally, each semiconductor die 200 may be any type of semiconductor die known in the art. For example, each of the at least one semiconductor die 200 in a unit area UA1 may comprise a system-on-chip (SoC) die, a logic die, a memory die, or a semiconductor die of any other type. In one embodiment, a semiconductor die 200 may comprise a die semiconductor substrate 210, which may comprise a single crystalline semiconductor substrate such as a single crystalline semiconductor substrate. Semiconductor devices 220 may be formed on a top surface of the die semiconductor substrate 210. The semiconductor devices 220 may comprise field effect transistors, resistors, diodes, capacitors, inductors, or any other type of semiconductor devices known in the art.

Metal interconnect structures 222 may be formed within dielectric material layers 230 and may also be formed over the semiconductor devices 220. The metal interconnect structures 222 may be electrically connected to the semiconductor devices 220, and may provide electrical interconnection for the semiconductor devices 220. Die-side bonding pads 224, i.e., bonding pads that are formed on a semiconductor die 200, may be formed at the topmost level of the dielectric material layers 230. In one embodiment, the semiconductor die 200 may be attached to the first carrier wafer 710 such that the die semiconductor substrate 210 is more proximal to the first carrier wafer 710 than the die-side bonding pads 224 are to the first carrier wafer 710. Planar horizontal surfaces of the die-side bonding pads 224 may be physically exposed after each semiconductor die 200 is attached to the first carrier wafer 710.

While the present disclosure is described using an embodiment in which a single semiconductor die 200 and a dummy die 201 are attached to the first carrier wafer 710 within each unit area UA1, embodiments are expressly contemplated herein in which two or more semiconductor dies 200 are attached to the first carrier wafer 710. Further embodiments are expressly contemplated herein in which the dummy die 201 is not used, or a plurality of dummy dies 201 is attached to the first carrier wafer 710 in each unit area UA1.

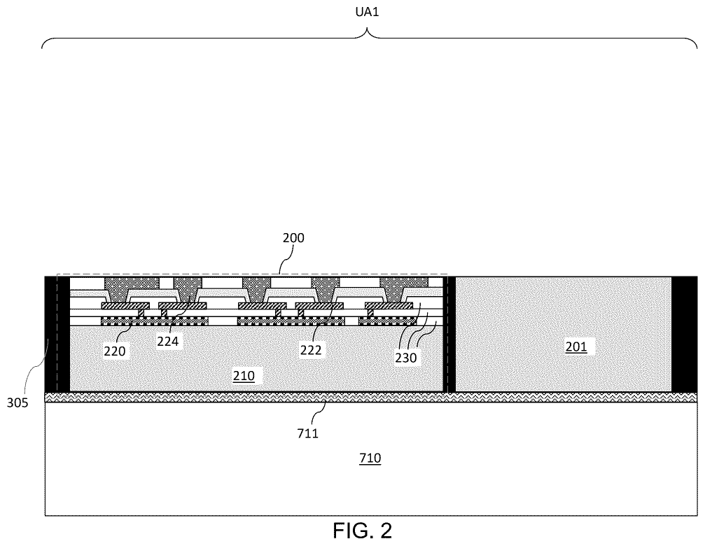

Referring to FIG. 2, an encapsulant, such as a molding compound (MC) material, may be applied to the gaps between neighboring pairs of dies (200, 201) attached to the first carrier wafer 710. The MC material may include an epoxy-containing compound that may be hardened (i.e., cured) to provide a dielectric material portion having sufficient stiffness and mechanical strength. The MC material may include epoxy resin, hardener, silica (as a filler material), and other additives. The MC material may be provided in a liquid form or in a solid form depending on the viscosity and flowability. Liquid MC materials typically provide better handling, good flowability, less voids, better fill, and less flow marks. Solid MC materials typically provide less cure shrinkage, better stand-off, and less die drift. A high filler content (such as 85% in weight) within an MC material may shorten the time in mold, lower the mold shrinkage, and reduce the mold warpage. Uniform filler size distribution in the MC material may reduce flow marks, and may enhance flowability.

The MC material may be cured at a curing temperature to form an MC matrix, which is herein referred to as a first MC matrix or a die-level MC matrix. The die-level MC matrix may be a continuous material layer that extends across the entirety of the first carrier wafer 710. Each portion of the die-level MC matrix located within a unit area UA1 constitutes a first molding compound frame, which is herein referred to as a molding compound die frame 305, or an MC die frame 305. Each MC die frame 305 laterally surrounds a set of at least one semiconductor die 200 and optionally at least one dummy die 201. A planarization process may be performed to remove portions of the MC material that overlies the horizontal plane including the topmost surfaces of the semiconductor dies 200. The top surfaces of the semiconductor dies 200 and the dummy dies 201 may be coplanar with the top surface of the die-level MC matrix. The combination of the semiconductor dies 200, the optional dummy dies 201, and the die-level MC matrix 305 constitutes a reconstituted wafer. The reconstituted wafer may comprise a two-dimensional array of reconstituted dies. Each reconstituted die may be located within a respective unit area UA1, and may comprise at least one semiconductor die 200, optionally at least one dummy die 201, and a molding compound die frame 305. The illustrated portion of the exemplary structure corresponds to a unit area UA1, i.e., a region including a single repetition unit within the reconstituted wafer.

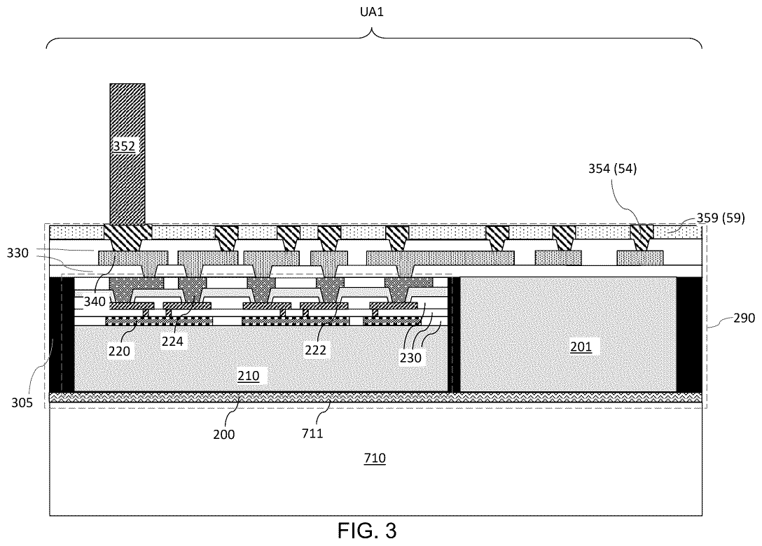

Referring to FIG. 3, fan-out redistribution wiring interconnects 340 formed within fan-out redistribution dielectric layers 330 may be formed over the reconstituted wafer including a two-dimensional array of reconstituted dies (200, 201, 305). The fan-out redistribution dielectric layers 330 include a respective dielectric polymer material such as polyimide (PI), benzocyclobutene (BCB), or polybenzobisoxazole (PBO). Other suitable dielectric polymer material may also be used. Each fan-out redistribution dielectric layer 330 may be formed by spin coating and drying of the respective dielectric polymer material. The thickness of each fan-out redistribution dielectric layer 330 may be in a range from 2 microns to 40 microns, such as from 4 microns to 20 microns. Each fan-out redistribution dielectric layer 330 may be patterned, for example, by applying and patterning a respective photoresist layer thereabove, and by transferring the pattern in the photoresist layer into the fan-out redistribution dielectric layer 330 using an etch process such as an anisotropic etch process. The photoresist layer may be subsequently removed, for example, by ashing.

Each of the fan-out redistribution wiring interconnects 340 may be formed by depositing a metallic seed layer by sputtering, by applying and patterning a photoresist layer over the metallic seed layer to form a pattern of openings through the photoresist layer, by electroplating a metallic fill material (such as copper, nickel, or a stack of copper and nickel), by removing the photoresist layer (for example, by ashing), and by etching portions of the metallic seed layer located between the electroplated metallic fill material portions. The metallic seed layer may include, for example, a stack of a titanium barrier layer and a copper seed layer. The titanium barrier layer may have thickness in a range from 50 nm to 300 nm, and the copper seed layer may have a thickness in a range from 100 nm to 500 nm. The metallic fill material for the fan-out redistribution wiring interconnects 340 may include copper, nickel, or copper and nickel. The thickness of the metallic fill material that is deposited for each fan-out redistribution wiring interconnects 340 may be in a range from 2 microns to 40 microns, such as from 4 microns to 10 microns, although lesser or greater thicknesses may also be used.

The fan-out redistribution wiring interconnects 340 at the topmost level may have general shapes of metal pads having a maximum lateral dimension in a range from 5 microns to 50 microns, such as from 10 microns to 40 microns, and/or from 15 microns to 30 microns, although lesser and greater maximum lateral dimensions may also be used. The lateral dimensions of bottom ends of via portions of the fan-out redistribution wiring interconnects 340 may be in a range from 2 microns to 10 microns, such as from 3 microns to 8 microns, although lesser and greater lateral dimensions may also be used. The total number of levels of the fan-out redistribution wiring interconnects 340 may be in a range from 1 to 20. The combination of the fan-out redistribution wiring interconnects 340 and the fan-out redistribution dielectric layers 330 within each unit area UA1 constitute a redistribution structure, which is herein referred to as a fan-out redistribution structure (330, 340) that is used to provide formation of fan-out bonding structures.

An array of metallic bump structures may be formed at the topmost level of the fan-out redistribution structure (330, 340) within each unit area UA1. The metallic bump structures are herein referred to as fan-out metallic bump structures 354 (i.e., metallic bump structures providing a fan-out configuration) or as die-side metallic bump structures 354 (i.e., metallic bump structures that are provided on the side of a die structure). The combination of a reconstituted die (200, 201, 305), a fan-out redistribution structure (330, 340), and an array of fan-out metallic bump structures 354 constitutes a composite semiconductor package, which may be referred to as a fan-out semiconductor package 290. The fan-out semiconductor package 290 is also referred to as a first-stage composite semiconductor package. Thus, upon formation of the fan-out redistribution structures (330, 340) and the fan-out metallic bump structures 354, the reconstituted die (200, 201, 305) comprises a two-dimensional array of fan-out semiconductor packages 290. Each fan-out semiconductor package 290 is a package structure, i.e., a structure that comprises at least one semiconductor die or an interposer that is assembled, or may be subsequently assembled, to form a composite structure that includes at least semiconductor die. The illustrated portion of the exemplary structure corresponds to a unit area UA1, i.e., a region including a single repetition unit within the reconstituted wafer.

The fan-out metallic bump structures 354 are bump structures that may be subsequently used to electrically connect the fan-out semiconductor package 290 to another package structure. The metallic fill material for the fan-out metallic bump structures 354 may include copper. Other suitable metallic fill materials are within the contemplated scope of disclosure. The fan-out metallic bump structures 354 may have horizontal cross-sectional shapes of rectangles, rounded rectangles, or circles. Other horizontal cross-sectional shapes may be within the contemplated scope of disclosure.

According to an aspect of the present disclosure, the fan-out metallic bump structures 354 may be formed as second metallic bump structures 54 may be subsequently bonded with first metallic bump structures to be provided in another package structure. Generally, as second metallic bump structures 54, the fan-out metallic bump structures 354 may be configured for microbump bonding (i.e., C2 bonding), and may have an overlying pillar portion and an underlying via portion. Each pillar portion of the second metallic bump structures 54 may have a height in a range from 5 microns to 30 microns, such as from 10 microns to 18 microns, although lesser or greater heights may also be used. Each pillar portion of the second metallic bump structures 54 may have a diameter in a range from 2 microns to 10 microns, such as from 3 microns to 8 microns, although lesser and greater diameters may also be used.

According to an aspect of the present disclosure, a polymer material layer that may be bonded to another polymer material layer through polymer-to-polymer bonding may be applied around the fan-out metallic bump structures 354 (which are second metallic bump structures 54). The polymer material layer is herein referred to as a fan-out polymer bonding layer 359, which functions as a second polymer bonding layer 59 to be subsequently used in a bonding process. Generally, the second polymer bonding layer 59 comprises a polymer material that may be bonded to another polymer material after a thermal anneal process. In one embodiment, the second polymer bonding layer 59 may comprise any of polyimide (PI), benzocyclobutene (BCB), and polybenzobisoxazole (PBO). Other suitable polymer materials that provide polymer-to-polymer bonding may also be used. As used herein, a polymer-to-polymer bonding is a bonding between two polymer materials that is provided by polymeric adhesion, which is formed by formation of atomic bonds between polymeric materials.

According to an aspect of the present disclosure, the second polymer bonding layer 59 may be formed over the second metallic bump structures 54 by spin coating to cover all surfaces of the second metallic bump structures 54. The second metallic bump structures 54 and the second polymer bonding layer 59 may be subsequently planarized, for example, by grinding and/or by chemical mechanical polishing. The height of the pillar portion of each second metallic bump structure 54 may be in a range from 2 microns to 10 microns, such as from 3 microns to 8 microns, although lesser and greater heights may also be used. The second polymer bonding layer 59 may be subsequently vertically recessed to physically expose top surfaces and topmost surface segments of sidewalls of the second metallic bump structures 54. The vertical recess distance of the top surface of the second polymer bonding layer 59 below the horizontal plane including the planar top surfaces of the second metallic bump structures 54 may be in a range from 0.2 microns to 1.0 microns, although lesser and greater vertical recess distances may also be used.

Optionally, through-interposer via (TIV) structures 352 may be formed on a subset of the fan-out metallic bump structures 354 (which are second metallic bump structures 54). In this embodiment, the subset of the fan-out metallic bump structures 354 may have suitable lateral dimensions (such as dimensions in a range from 15 microns to 60 microns) for accommodating the fan-out metallic bump structures 354. The fan-out metallic bump structures 354 may be formed, for example, by using a sacrificial deposition mask layer and at least metal deposition process (such as an electroplating process, a physical vapor deposition process, etc.) or by attaching pre-fabricated TIV structures 352. The height of the TIV structures 352 may be in a range from 30 microns to 300 microns, although lesser and greater heights may also be used.

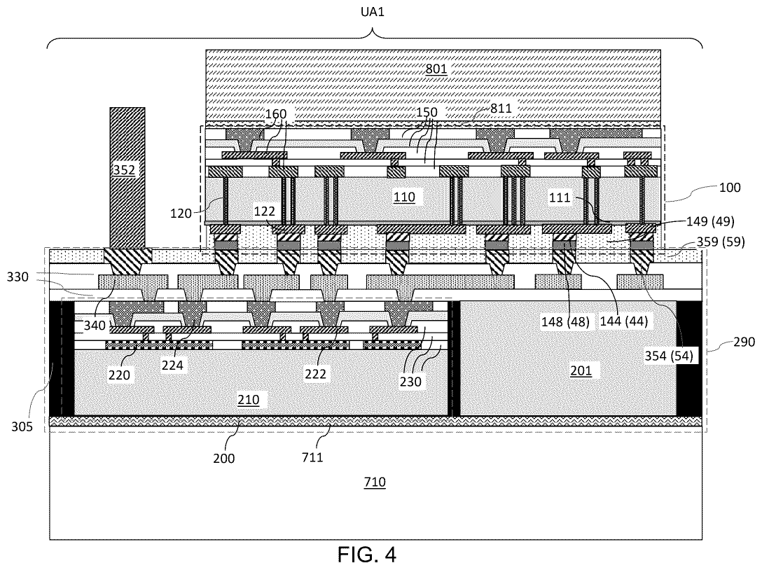

Referring to FIG. 4, an array of first semiconductor interposers 100 may be provided on a carrier wafer, and may be subsequently diced to provide a stack of a first semiconductor interposer 100 and a carrier substrate 801. The first semiconductor interposer 100 is one of the first semiconductor interposers 100 from the array. The carrier substrate 801 is a diced portion of the carrier wafer.

The first semiconductor interposer 100 may comprise a first semiconductor substrate 110 and first through-substrate via (TSV) structures 120 that vertically extend through the first semiconductor substrate 110. Redistribution wiring interconnects formed within redistribution dielectric layers may be formed on a first side of the first semiconductor substrate 110. The redistribution wiring interconnects are herein referred to as first distal redistribution wiring interconnects 160, and the redistribution dielectric layers are herein referred to as first distal redistribution dielectric layers 150.

In an illustrative example, the first semiconductor substrate 110 may be provided as a portion of a semiconductor wafer including a two-dimensional array of first semiconductor substrates 110, and the first TSV structures 120 may be formed in an upper portion of the semiconductor wafer. In one embodiment, a commercially available single crystalline silicon wafer may be used as the semiconductor wafer. The first distal redistribution wiring interconnects 160 and the first distal redistribution dielectric layers 150 may be formed on a first side of the semiconductor wafer. The set of processing steps used to form the first distal redistribution wiring interconnects 160 and the first distal redistribution dielectric layers 150 may be similar to the set of processing steps used to form the fan-out redistribution wiring interconnects 340 and the fan-out redistribution dielectric layers 330.

A carrier wafer 801 may be attached to the first distal redistribution dielectric layers 150 using an adhesive layer 811. In one embodiment, the carrier wafer 801 may comprise an additional semiconductor wafer, which may be a polycrystalline silicon wafer or a single crystalline silicon wafer. The backside of the semiconductor wafer including an array of first semiconductor substrates 110 may be removed, for example, by grinding, polishing, an anisotropic etch process, and/or an isotropic etch process. End surfaces of the first TSV structures 120 may be exposed upon thinning of the semiconductor wafer. The backside surface of the semiconductor wafer may be recessed relative to the physically exposed surfaces of the first TSV structures 120. A planar insulating layer 111 may be formed on the physically exposed backside surface of the thinned semiconductor wafer. Proximal redistribution wiring interconnects 122 and optionally proximal redistribution layers (not expressly illustrated) may be formed on the physically exposed surfaces of the first TSV structures 120.

Proximal metallic bump structures 144 and first solder material portions 148 may be formed on the proximal redistribution wiring interconnects 122. The proximal metallic bump structures 144 function as first metallic bump structures 44, and the first solder material portions 148 function as solder material portions 48. Generally, as first metallic bump structures 44, the proximal metallic bump structures 144 may be configured for microbump bonding (i.e., C2 bonding), and may have an overlying pillar portion and an underlying via portion. Each pillar portion of the first metallic bump structures 44 may have a height in a range from 2 microns to 10 microns, such as from 3 microns to 8 microns, although lesser or greater heights may also be used. Each pillar portion of the first metallic bump structures 44 may have a diameter in a range from 2 microns to 10 microns, such as from 3 microns to 8 microns, although lesser and greater diameters may also be used.

According to an aspect of the present disclosure, a polymer material layer that may be bonded to another polymer material layer through polymer-to-polymer bonding may be applied around the proximal metallic bump structures 144 (which are first metallic bump structures 44). The polymer material layer is herein referred to as a proximal polymer bonding layer 149, which functions as a first polymer bonding layer 49 to be subsequently used in a bonding process. Generally, the first polymer bonding layer 49 comprises a polymer material that may be bonded to another polymer material after a thermal anneal process. In one embodiment, the first polymer bonding layer 49 may comprise any of polyimide (PI), benzocyclobutene (BCB), and polybenzobisoxazole (PBO). Other suitable polymer materials that provide polymer-to-polymer bonding may also be used.

According to an aspect of the present disclosure, the first polymer bonding layer 49 may be formed over the solder material portions 48 (which may comprise the first solder material portions 148) by spin coating to cover all surfaces of the solder material portions 48. The solder material portions 48 and the first polymer bonding layer 49 may be subsequently planarized, for example, by grinding and/or by chemical mechanical polishing. The height of each remaining solder material portion 48 may be in a range from 2 microns to 6 microns, such as from 2.5 microns to 5 microns, although lesser and greater heights may also be used. The solder material portions 48 may be subsequently vertically recessed by a vertical recess distance in a range from 0.2 micron to 1 micron. The height of each remaining solder material portion 48 after the recess process may be in a range from 1.8 microns to 5 microns, such as from 2 microns to 4 microns, although lesser and greater heights may also be used.

The combination of the semiconductor wafer having formed thereon the first TSV structures 120, the combination of the first distal redistribution wiring interconnects 160 and the first distal redistribution dielectric layers 150, the proximal redistribution wiring interconnects 122 and proximal redistribution layers (if any), the carrier wafer, and the adhesive layer 811 between the carrier wafer and the first distal redistribution dielectric layers 150 may be diced along dicing channels. Each diced portion of the combination of the semiconductor wafer embedding the first TSV structures 120, the combination of the first distal redistribution wiring interconnects 160 and the first distal redistribution dielectric layers 150, the proximal redistribution wiring interconnects 122 and proximal redistribution layers (if any) constitutes a first semiconductor interposer 100, which functions as a first package structure. Each diced portion of the carrier wafer constitutes a carrier substrate 801, which may comprise a silicon substrate having a thickness in a range from 200 microns to 1 mm, and providing structural support to the first semiconductor interposer 100. In this embodiment, the carrier substrate 801 may be used to handle the first semiconductor interposer 100 while the first semiconductor interposer 100 is attached to the fan-out semiconductor package 290.

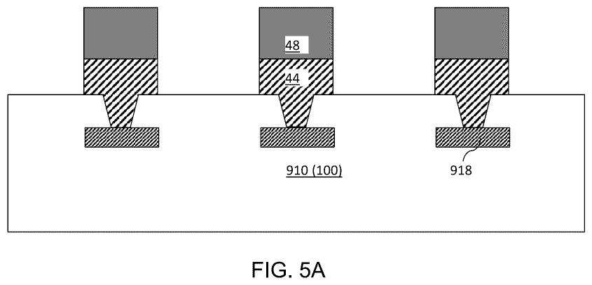

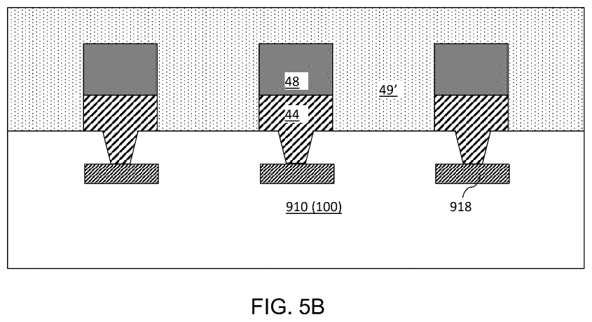

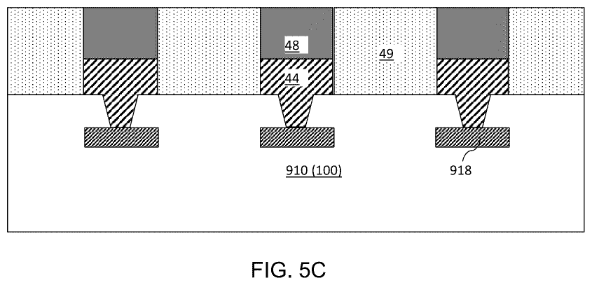

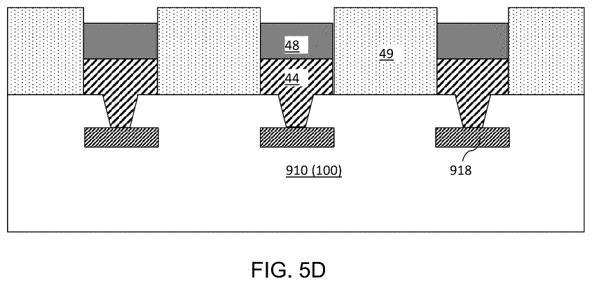

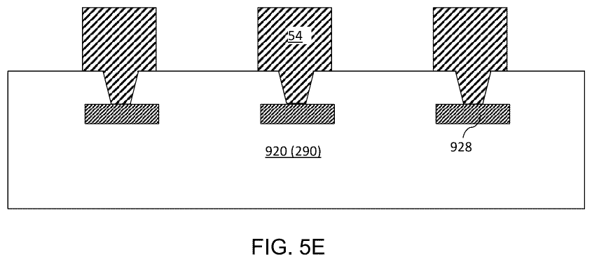

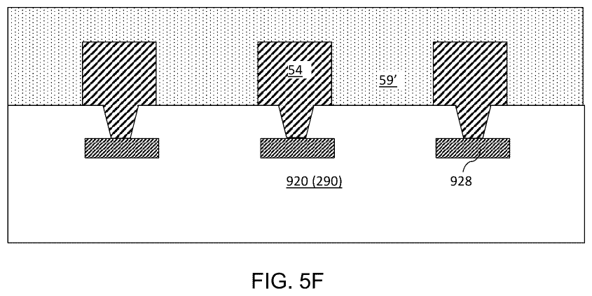

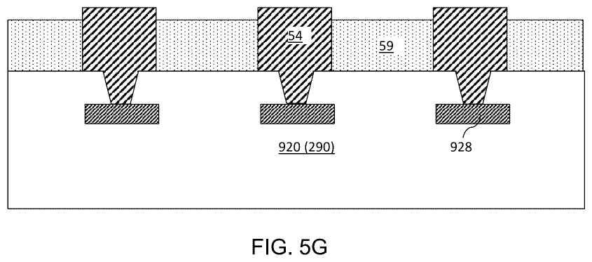

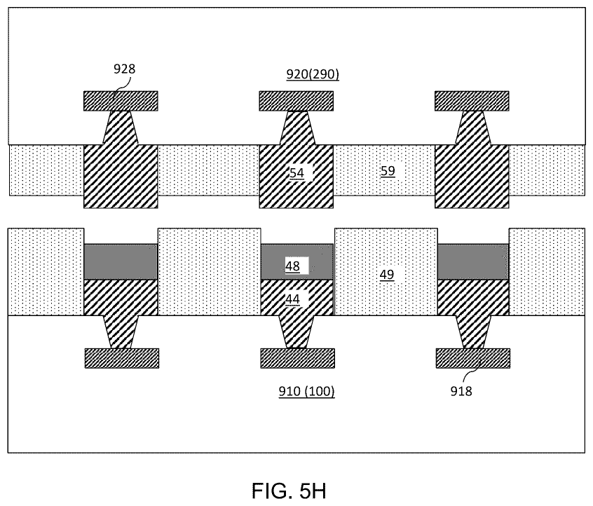

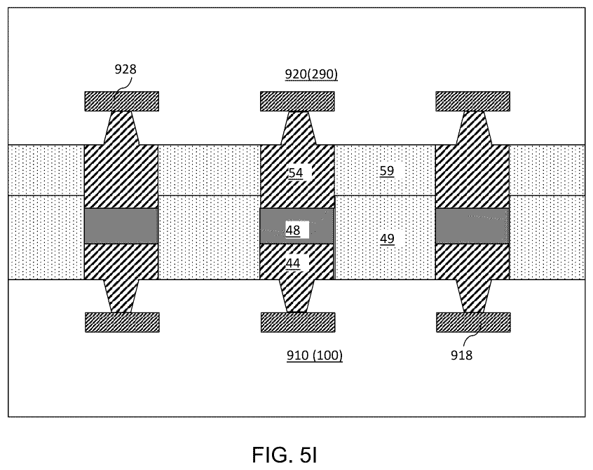

FIGS. 5A-5I illustrate sequential vertical cross-sectional views of exemplary package structures that may be bonded using a hybrid bonding process of the present disclosure. In the example illustrated in FIGS. 5A-5I, a first package structure 910 is provided, which may comprise a first semiconductor interposer 100 illustrated in FIG. 4, or may comprise any other package structure. A second package structure 920 is provided, which may comprise a fan-out semiconductor package 290 illustrated in FIG. 4, or may comprise any other package structure. The processing steps described with reference to FIGS. 5A-5I may be used to provide bonding between the first semiconductor interposer 100 and the fan-out semiconductor package 290 with accompanying polymer-to-polymer bonding between the proximal polymer bonding layer 149 (as a first polymer bonding layer 49) and the fan-out polymer bonding layer 359 (as a second polymer bonding layer 59).

Referring to FIG. 5A, a portion of a first package structure 910 is illustrated, which may comprise a first semiconductor interposer 100 or as any other package structure. The first package structure 910 may comprise first metallic interconnection structures 918 therein, which may comprise, for example, first TSV structures 120, proximal redistribution wiring interconnects 122, first distal redistribution wiring interconnects 160, etc. as in the embodiment of the first semiconductor interposer 100. First metallic bump structures 44 may be formed on the first package structure 910. For example, the first metallic bump structures 44 may comprise proximal metallic bump structures 144. Generally, the first metallic bump structures 44 may be electrically connected to the first metallic interconnection structures 918.

Solder material portions 48 (which may comprise the first solder material portions 148) are bonded to the first metallic bump structures 44. The first metallic bump structures 44 may be configured for microbump bonding (i.e., C2 bonding). In one embodiment, each first metallic bump structure 44 may have an upper pillar portion and a lower via portion. The first metallic bump structures 44 and the solder material portions 48 may be formed by deposition and patterning of a metallic bump material and a solder material, and each stack of an upper pillar portion of a first metallic bump structure 44 and a solder material portion 48 may have a same horizontal cross-sectional shape.

Each pillar portion of the first metallic bump structures 44 and each solder material portion 48 may have a diameter in a range from 2 microns to 10 microns, such as from 3 microns to 8 microns, although lesser and greater diameters may also be used. Each pillar portion of the first metallic bump structures 44 may have a height in a range from 2 microns to 10 microns, such as from 3 microns to 8 microns, although lesser or greater heights may also be used. Each solder material portion 48 as formed on a first metallic bump structure 44 may have a height in a range from 3 microns to 15 microns, such as from 5 microns to 10 microns, although lesser and greater heights may also be used. In one embodiment, the pitch of the upper pillar portions of the first metallic bump structures 44 and the solder material portions 48 may be in a range from 4 microns to 20 microns, although lesser and greater pitches may also be used.

Referring to FIG. 5B, a first polymer material layer 49′ may be formed over the first metallic bump structures 44. The first polymer material layer 49′ is a polymer bonding layer that is subsequently modified. The first polymer material layer 49′ may comprise any of polyimide (PI), benzocyclobutene (BCB), and polybenzobisoxazole (PBO). Other suitable polymer materials that provide polymer-to-polymer bonding may also be used. In one embodiment, the first polymer material layer 49′ may be formed by spin coating. The thickness of the first polymer material layer 49′ may be selected such that the solder material portions 48 are covered by the first polymer material layer 49′. The first polymer material layer 49′ may be cured by performing a first anneal process at a first elevated temperature, which may be in a range from 150 degrees Celsius to 200 degrees Celsius. The duration of the first anneal process may be in a range from 10 minutes to 200 minutes, although lesser and greater durations may also be used.

Referring to FIG. 5C, a planarization process may be performed to remove upper portions of the first polymer material layer 49′ and the solder material portions 48. The planarization process may comprise a grinding process and/or a chemical mechanical polishing process. The remaining portion of the first polymer material layer 49′ constitutes a first polymer bonding layer 49. The height of the solder material portions 48 after the planarization process may be in a range from 2 microns to 6 microns, such as from 2.5 microns to 5 microns, although lesser and greater heights may also be used. The top surface of the first polymer bonding layer 49 may be coplanar with the top surfaces of the remaining portions of the solder material portions 48.

Referring to FIG. 5D, the solder material portions 48 may be subsequently vertically recessed, for example, by performing a plasma dry etch process selective to the first polymer bonding layer 49. The vertical recess distance may be in a range from 0.2 micron to 1 micron. The height of each remaining solder material portion 48 after the recess process may be in a range from 1.8 microns to 5 microns, such as from 2 microns to 4 microns, although lesser and greater heights may also be used.

Referring collectively to FIGS. 5B-5D, a first polymer material layer 49′ having a planar top surface may be formed over the first metallic bump structures 44 (which may comprise proximal metallic bump structures 144). The first polymer material layer 49′ may be vertically recessed until top surfaces of the solder material portions 48 (which may comprise first solder material portions 148) are exposed. The first polymer bonding layer 49 (which may comprise a proximal polymer bonding layer 149) is formed. The solder material portions 48 (which may comprise first solder material portions 148) may be vertically recessed selective to the first polymer bonding layer 49 (which may comprise a proximal polymer bonding layer 149). Specifically, physically exposed surfaces of the solder material portions 48 (which may comprise first solder material portions 148) may be vertically recessed relative to a physically exposed surface of the first polymer bonding layer 49 (which may comprise a proximal polymer bonding layer 149).

Referring to FIG. 5E, a portion of a second package structure 920 is illustrated, which may comprise a fan-out semiconductor package 290 or as any other package structure. The second package structure 920 may comprise second metallic interconnection structures 928 therein, which may comprise, for example, metal interconnect structures 222, die-side bonding pads 224, fan-out redistribution wiring interconnects 340, etc. as in the embodiment of the fan-out semiconductor package 290. Second metallic bump structures 54 may be formed on the second package structure 920. For example, the second metallic bump structures 54 may comprise fan-out metallic bump structures 354. Generally, the second metallic bump structures 54 may be electrically connected to the second metallic interconnection structures 928.

In one embodiment, each second metallic bump structure 54 may have an upper pillar portion and a lower via portion. The second metallic bump structures 54 may be formed by deposition and patterning of a metallic bump material. The pillar portions of the second metallic bump structures 54 may have the same diameter as the pillar portions of the first metallic bump structures 44 and the solder material portions 48. Each pillar portion of the second metallic bump structures 54 may have a height in a range from 5 microns to 30 microns, such as from 10 microns to 18 microns, although lesser or greater heights may also be used. The pattern of the second metallic bump structures 54 may be a mirror image pattern of the pattern of the first metallic bump structures 44.

Referring to FIG. 5F, a second polymer material layer 59′ may be formed over the second metallic bump structures 54. The second polymer material layer 59′ is a polymer bonding layer that is subsequently modified. The second polymer material layer 59′ may comprise any of polyimide (PI), benzocyclobutene (BCB), and polybenzobisoxazole (PBO). Other suitable polymer materials that provide polymer-to-polymer bonding may also be used. The material of the second polymer material layer 59′ may be the same as, or may be different from, the material of the first polymer material layer 49′. In one embodiment, the second polymer material layer 59′ may be formed by spin coating. The thickness of the second polymer material layer 59′ may be selected such that the second metallic bump structures 54 are covered by the second polymer material layer 59′. The second polymer material layer 59′ may be cured by performing a second anneal process at a second elevated temperature, which may be in a range from 150 degrees Celsius to 200 degrees Celsius. The duration of the second anneal process may be in a range from 10 minutes to 200 minutes, although lesser and greater durations may also be used.

Referring to FIG. 5G, a planarization process may be performed to remove upper portions of the second polymer material layer 59′. The planarization process may comprise a grinding process and/or a chemical mechanical polishing process. The second metallic bump structures 54 and the second polymer material layer 59′ may be subsequently planarized, for example, by grinding and/or by chemical mechanical polishing. The height of the pillar portion of each second metallic bump structure 54 after the planarization process may be in a range from 2 microns to 10 microns, such as from 3 microns to 8 microns, although lesser and greater heights may also be used.

The second polymer material layer 59′ may be subsequently vertically recessed to physically expose top surfaces and topmost surface segments of sidewalls of the second metallic bump structures 54. The remaining portion of the second polymer material layer 59′ after the recess process constitutes a second polymer bonding layer 59. The vertical recess distance of the top surface of the second polymer bonding layer 59 below the horizontal plane including the planar top surfaces of the second metallic bump structures 54 may be in a range from 0.2 microns to 1.0 microns, although lesser and greater vertical recess distances may also be used.

The material of the second polymer bonding layer 59 may be the same as, or may be different from, the material of the first polymer bonding layer 49. In one embodiment, the material of the second polymer bonding layer 59 may be different from the material of the first polymer bonding layer 49. In one embodiment, materials of the second polymer bonding layer 59 and the first polymer bonding layer 49 such that the second polymer bonding layer 59 and the first polymer bonding layer 49 provide strong polymer-to-polymer bonding upon contact and a subsequent anneal process. In one embodiment, the first polymer bonding layer 49 may comprise a first component of a two-component adhesive material such as an epoxy, and the second polymer bonding layer 59 may comprise a second component of the two-component adhesive material. In a non-limiting illustrative example, the first polymer bonding layer 49 may comprise a first component polymer material (such as epoxy resin) for forming epoxy, and the second polymer bonding layer 59 may comprise a second component polymer material (such as a curing agent) for forming the epoxy.

Referring collectively to FIGS. 5E-5G, a second package structure 920 (such as a fan-out semiconductor package 290) comprising second metallic interconnection structures 928 (which may comprise metal interconnect structures 222, die-side bonding pads 224, fan-out redistribution wiring interconnects 340), second metallic bump structures 54 (which may comprise fan-out metallic bump structures 354) electrically connected to the second metallic interconnection structures 928, and a second polymer bonding layer 59 (which may comprise a fan-out polymer bonding layer 359) laterally surrounding the second metallic bump structures 54 (which may comprise fan-out metallic bump structures 354) is provided. In one embodiment, the second package structure 920 may be provided by forming a second polymer material layer 59′ having a planar top surface over the second metallic bump structures 54, and by vertically recessing a top surface of the second polymer material layer 59′ below a horizontal plane including top surfaces of the second metallic bump structures 54. A remaining portion of the second polymer material layer 59′ comprises the second polymer bonding layer 59.

Referring to FIG. 5H, the second package structure 920 may be positioned to face the first package structure 910, and the second metallic bump structures 54 of the second package structure 920 may be aligned to the solder material portions 48 on the first package structure 910. The first polymer bonding layer 49 and the second polymer bonding layer 59 may be pre-heated to a temperature in a range from 150 degrees Celsius to 200 degrees Celsius for a duration, which may be in a range from 1 second to 20 seconds.

Referring to FIG. 5I, a hybrid bonding process including a combination of a solder bonding and a polymer-to-polymer bonding may be performed. Specifically, the second metallic bump structures 54 are brought into contact with the solder material portions 48. The assembly of the first package structure 910 and the second package structure 920 may be heated to, or above, the solder reflow temperature to induce reflow of the solder material portions 48, and to induce bonding between the solder material portions 48 and the second metallic bump structures 54. The elevated temperature of the reflow process may be in a range from 250 degrees to 300 degrees Celsius, and the duration of the reflow process may be in a range from 10 seconds to 60 seconds. Subsequently, while the solder material portions 48 are at, or below, the reflow temperature, the assembly of the first package structure 910 and the second package structure 920 may be annealed at an elevated temperature to induce polymer-to-polymer bonding between the first polymer bonding layer 49 and the second polymer bonding layer 59. The elevated temperature may be in a range from 200 degrees Celsius to 300 degrees Celsius. The duration of the anneal process may be in a range from 30 minutes to 3 hours, although lesser and greater durations may also be used.

Generally, the second metallic bump structures 54 (which may comprise fan-out metallic bump structures 354) may be bonded to the first metallic bump structures 44 (which may comprise proximal metallic bump structures 144) by performing a bonding process in which the solder material portions 48 (which may comprise first solder material portions 148) are reflowed while the second metallic bump structures 54 (which may comprise fan-out metallic bump structures 354) contact the solder material portions 48 and while the second polymer bonding layer 59 (which may comprise a fan-out polymer bonding layer 359) contacts the first polymer bonding layer 49 (which may comprise a proximal polymer bonding layer 149). In one embodiment, the second polymer bonding layer 59 (which may comprise a fan-out polymer bonding layer 359) is bonded to the first polymer bonding layer 49 (which may comprise a proximal polymer bonding layer 149) while the solder material portions 48 reflow.

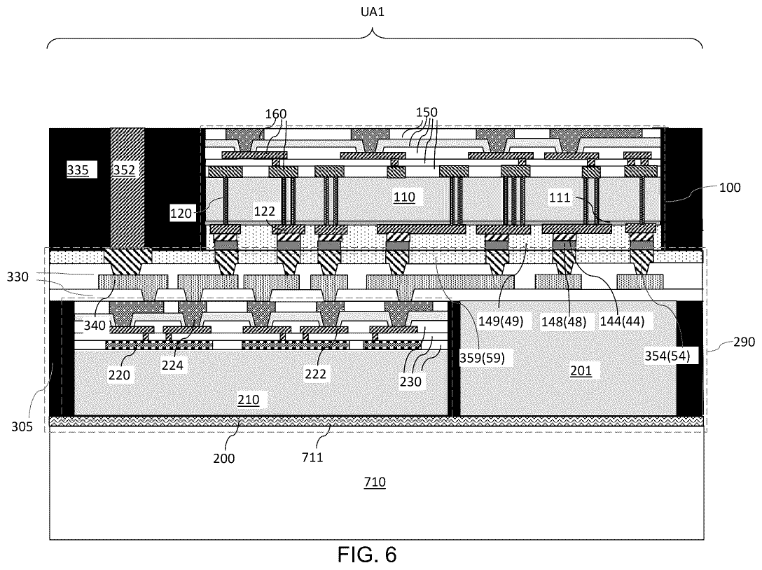

Referring to FIG. 6, each carrier substrate 801 may be detached from a respective first semiconductor interposer 100. A suitable clean process may be performed to remove the adhesive layer 811. An encapsulant, such as a molding compound (MC) material, may be applied around the array of first semiconductor interposers 100 and the TIV structures 352. The MC material may comprise any of the materials that may be used for the molding compound die matrix, which is described with reference to FIG. 2. A molding compound interposer matrix may be formed around the array of first semiconductor interposers 100 and the TIV structures 352. Each portion of the molding compound interposer matrix that is located within a unit area UA1 is herein referred to as a molding compound interposer frame 335, or an MC interposer frame 335. Each MC interposer frame 335 laterally surrounds a first semiconductor interposer 100 and optionally a set of TIV structures 352.

A planarization process may be performed to remove portions of the MC material that overlies the horizontal plane including the topmost surfaces of the first semiconductor interposers 100. The top surface of the MC material may be coplanar with the top surfaces of the first semiconductor interposers 100 and remaining portions of the TIV structures 352. The reconstituted wafer now comprises a two-dimensional array of combinations of a fan-out semiconductor package 290, a first semiconductor interposer 100, optional TIV structures 352, and a molding compound frame which is a molding compound interposer frame 335. As discussed above, the illustrated portion of the exemplary structure corresponds to a unit area UA1, i.e., a region including a single repetition unit within the reconstituted wafer.

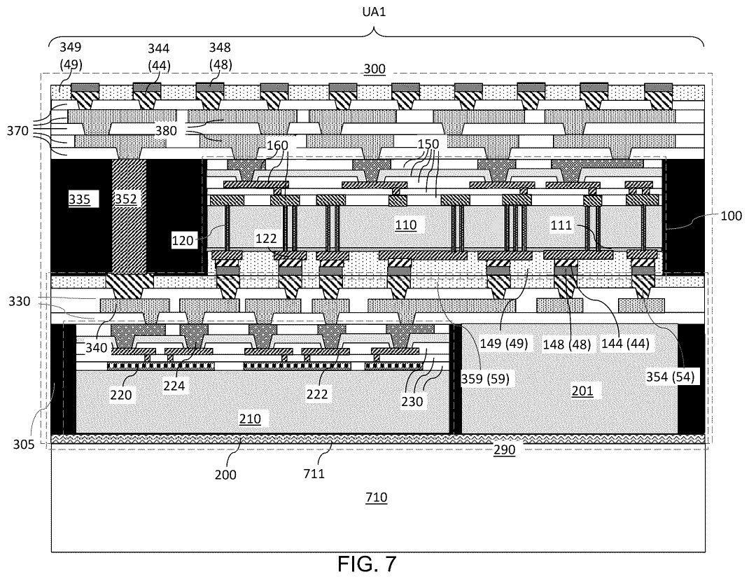

Referring to FIG. 7, redistribution wiring interconnects formed within redistribution dielectric layers may be formed over the first distal redistribution wiring interconnects 160 and the first distal redistribution dielectric layers 150. The redistribution wiring interconnects that are formed at this processing step are herein referred to as second distal redistribution wiring interconnects 380. The redistribution dielectric layers that are formed at this processing step are herein referred to as second distal redistribution dielectric layers 370. The set of processing steps used to form the second distal redistribution wiring interconnects 380 and the second distal redistribution dielectric layers 370 may be similar to the set of processing steps used to form the fan-out redistribution wiring interconnects 340 and the fan-out redistribution dielectric layers 330.

Subsequently, the processing steps described with reference to FIGS. 5A-5D may be performed mutatis mutandis to form distal metallic bump structures 344, second solder material portions 348, and a distal polymer bonding layer 349. In this embodiment, the second distal redistribution wiring interconnects 380 constitute components of the first metallic interconnection structures 918 in FIGS. 5A-5D on which the first metallic bump structures 44 are formed. The distal metallic bump structures 344 correspond to the first metallic bump structures 44 in FIGS. 5A-5D. The second solder material portions 348 correspond to the solder material portions 48 in FIGS. 5A-5D. The distal polymer bonding layer 349 corresponds to the first polymer bonding layer 49 in FIGS. 5C and 5D.

The combination of all material portions within each unit area UA1 other than the second solder material portions 348, the first carrier wafer 710, and the first DAF 711 constitutes a die-interposer assembly 300, which is an assembly including at least one semiconductor die 200 and a first semiconductor interposer 100. Each die-interposer assembly 300 is a second-stage composite package, which incorporates a first-stage composite package. The reconstituted wafer now comprises a two-dimensional array of die-interposer assemblies 300. As discussed above, the illustrated portion of the exemplary structure corresponds to a unit area UA1, i.e., a region including a single repetition unit within the reconstituted wafer.

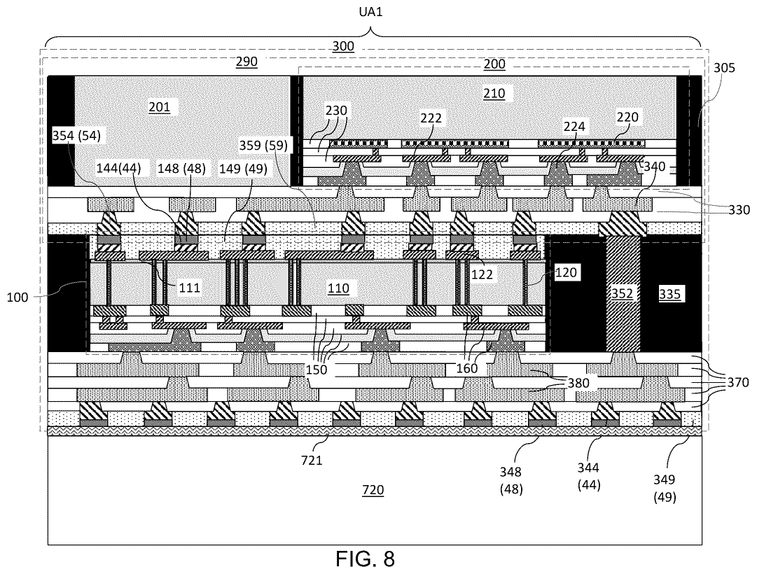

Referring to FIG. 8, a second carrier wafer 720 may be attached to the reconstituted wafer using a second DAF 721. The second carrier wafer 720 may comprise an optically transparent material such as glass. If the first carrier wafer 710 comprises an optically transparent material such as glass, the first DAF 711 may be irradiated with energetic photons (such as ultraviolet photons) to induce breakage of chemical bonds therein. The first carrier wafer 710 may be detached from the assembly of the reconstituted wafer and the second carrier wafer 720.

A grinding process may be performed to thin the backside of the semiconductor dies 200 and the dummy dies 201. The thickness of the die semiconductor substrate 210 of each semiconductor die 200 may be in a range from 30 microns to 300 microns, although lesser and greater thicknesses may also be used. As discussed above, the illustrated portion of the exemplary structure corresponds to a unit area UA1, i.e., a region including a single repetition unit within the reconstituted wafer.

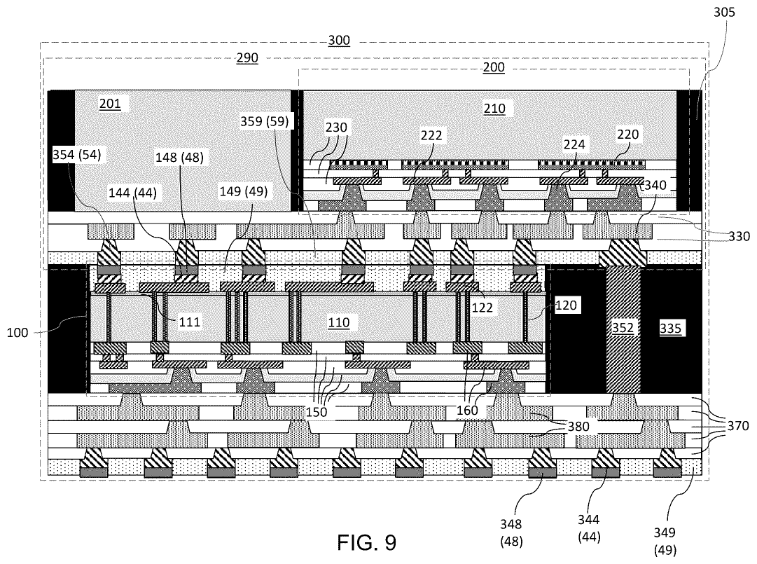

Referring to FIG. 9, the second DAF 721 may be irradiated through the second carrier wafer 720 with energetic photons (such as ultraviolet photons) to induce breakage of chemical bonds therein. The second carrier wafer 720 may be detached from the reconstituted wafer. The reconstituted wafer may be mounted on a dicing frame, and may be subsequently diced along dicing channels (which are boundaries between neighboring pairs of unit areas UA1). The reconstituted wafer is diced into discrete die-interposer assembly 300. Each die-interposer assembly 300 is a second-stage composite package. Thus, an array of second-stage composite packages may be singulated into discrete second-stage composite packages (i.e., discrete die-interposer assemblies 300). A single die-interposer assembly 300 is illustrated in FIG. 9.

Referring collectively to FIGS. 51 and 9, a bonded assembly is provided, which comprises: a first package structure 910 (which may comprise a first semiconductor interposer 100) comprising first metallic interconnection structures 918 (such as first TSV structures 120, and proximal redistribution wiring interconnects 122, and first distal redistribution wiring interconnects 160), first metallic bump structures 44 (which may comprise proximal metallic bump structures 144) electrically connected to the first metallic interconnection structures 918, and a first polymer bonding layer 49 (which may comprise a proximal polymer bonding layer 149) laterally surrounding the first metallic bump structures 44 (which may comprise proximal metallic bump structures 144); a second package structure 920 (such as a fan-out semiconductor package 290) comprising second metallic interconnection structures 928 (which may comprise metal interconnect structures 222, die-side bonding pads 224, fan-out redistribution wiring interconnects 340, etc.), second metallic bump structures 54 (which may comprise fan-out metallic bump structures 354) electrically connected to the second metallic interconnection structures 928, and a second polymer bonding layer 59 (which may comprise a fan-out polymer bonding layer 359) laterally surrounding the second metallic bump structures 54 (which may comprise fan-out metallic bump structures 354); and solder material portions 48 (which may comprise first solder material portions 148) located between the first metallic bump structures 44 and the second metallic bump structures 54. Each of the solder material portions 48 is bonded to a respective one of the first metallic bump structures 44 and a respective one of the second metallic bump structures 54); and the second polymer bonding layer 59 is bonded to the first polymer bonding layer 49 through polymer-to-polymer bonding.

In one embodiment, the first package structure 910 (which may comprise a first semiconductor interposer 100) comprises a first semiconductor substrate 110 including first through-substrate via structures 120 therethrough. The first metallic interconnection structures 918 (such as first TSV structures 120, proximal redistribution wiring interconnects 122, and first distal redistribution wiring interconnects 160) comprise the first through-substrate via structures 120. In one embodiment, the first package structure 910 is laterally surrounded by a molding compound frame (such as a molding compound interposer frame 335) that laterally surrounds the first semiconductor substrate 110.

In one embodiment, the first metallic interconnection structures 918 (such as first TSV structures 120, proximal redistribution wiring interconnects 122, and first distal redistribution wiring interconnects 160) comprise first redistribution wiring interconnects (such as first distal redistribution wiring interconnects 160) that are formed within first redistribution dielectric layers (such as first distal redistribution dielectric layers 150); and the first redistribution dielectric layers (such as first distal redistribution dielectric layers 150) are laterally surrounded by the molding compound frame (such as a molding compound interposer frame 335).

In one embodiment, the first metallic interconnection structures 918 (such as first TSV structures 120, proximal redistribution wiring interconnects 122, and first distal redistribution wiring interconnects 160) comprise second redistribution wiring interconnects (such as second distal redistribution wiring interconnects 380) that are formed within second redistribution dielectric layers (such as second distal redistribution dielectric layers 370); and the second redistribution dielectric layers (such as second distal redistribution dielectric layers 370) comprise a horizontal surface that contacts the molding compound frame (such as a molding compound interposer frame 335) and comprise sidewalls that are vertically coincident with outer sidewalls of the molding compound frame (such as a molding compound interposer frame 335).

In one embodiment, the second package structure 920 (such as a fan-out semiconductor package 290) comprises: an additional semiconductor substrate (such as a die semiconductor substrate 210); and field effect transistors (which are a subset of the semiconductor devices 220) located on the additional semiconductor substrate (such as the die semiconductor substrate 210). The second metallic interconnection structures 928 (which may comprise metal interconnect structures 222, die-side bonding pads 224, fan-out redistribution wiring interconnects 340, etc.) comprise metal interconnect structures 222 that are electrically connected to the field effect transistors.

In one embodiment, a horizontal bonding interface between the second polymer bonding layer 59 (which may comprise a fan-out polymer bonding layer 359) and the first polymer bonding layer 49 (which may comprise a proximal polymer bonding layer 149) is more distal from a horizontal plane including a proximal horizontal surface of the first semiconductor substrate 110 of the first package structure 910 (which may comprise a first semiconductor interposer 100) than interfaces between the solder material portions 48 (which may comprise first solder material portions 148) and the second metallic bump structures 54 (which may comprise fan-out metallic bump structures 354) are from the proximal horizontal surface of the first semiconductor substrate 110 of the first package structure 910 (which may comprise a first semiconductor interposer 100).

In one embodiment, each of the solder material portions 48 (which may comprise first solder material portions 148) is laterally surrounded by, and is contacted by, the first polymer bonding layer 49 (which may comprise a proximal polymer bonding layer 149). In one embodiment, the second polymer bonding layer 59 (which may comprise a fan-out polymer bonding layer 359) is spaced from, and does not contact, the solder material portions 48 (which may comprise first solder material portions 148).

In one embodiment, the first polymer bonding layer 49 (which may comprise a proximal polymer bonding layer 149) is spaced from, and does not contact, the second package structure 920 (such as a fan-out semiconductor package 290); and the second polymer bonding layer 59 (which may comprise a fan-out polymer bonding layer 359) is spaced from, and does not contact, the first package structure 910 (which may comprise a first semiconductor interposer 100).

According to another aspect of the present disclosure, a bonded assembly is provided, which comprises: a first package structure 910 (which may comprise a first semiconductor interposer 100) comprising first metallic interconnection structures 918 (such as first TSV structures 120, proximal redistribution wiring interconnects 122, and first distal redistribution wiring interconnects 160), first metallic bump structures 44 (which may comprise proximal metallic bump structures 144) electrically connected to the first metallic interconnection structures 918 (such as first TSV structures 120, proximal redistribution wiring interconnects 122, and first distal redistribution wiring interconnects 160), and a first polymer bonding layer 49 (which may comprise a proximal polymer bonding layer 149) laterally surrounding the first metallic bump structures 44 (which may comprise proximal metallic bump structures 144); a second package structure 920 (such as a fan-out semiconductor package 290) comprising second metallic interconnection structures 928 (which may comprise metal interconnect structures 222, die-side bonding pads 224, fan-out redistribution wiring interconnects 340), second metallic bump structures 54 (which may comprise fan-out metallic bump structures 354) electrically connected to the second metallic interconnection structures 928 (which may comprise metal interconnect structures 222, die-side bonding pads 224, fan-out redistribution wiring interconnects 340), and a second polymer bonding layer 59 (which may comprise a fan-out polymer bonding layer 359) laterally surrounding the second metallic bump structures 54 (which may comprise fan-out metallic bump structures 354); and solder material portions 48 (which may comprise first solder material portions 148) located between the first metallic bump structures 44 (which may comprise proximal metallic bump structures 144) and the second metallic bump structures 54 (which may comprise fan-out metallic bump structures 354). Each of the solder material portions 48 (which may comprise first solder material portions 148) is bonded to a respective one of the first metallic bump structures 44 (which may comprise proximal metallic bump structures 144) and a respective one of the second metallic bump structures 54 (which may comprise fan-out metallic bump structures 354), is laterally surrounded by the first polymer bonding layer 49 (which may comprise a proximal polymer bonding layer 149), and is not in direct with the second polymer bonding layer 59 (which may comprise a fan-out polymer bonding layer 359). The first polymer bonding layer 49 (which may comprise a proximal polymer bonding layer 149) is spaced from the second package structure 920 (such as a fan-out semiconductor package 290) by the second polymer bonding layer 59 (which may comprise a fan-out polymer bonding layer 359).

In one embodiment, the second polymer bonding layer 59 (which may comprise a fan-out polymer bonding layer 359) is bonded to the first polymer bonding layer 49 (which may comprise a proximal polymer bonding layer 149) by polymer-to-polymer bonding. In one embodiment, the first package structure 910 (which may comprise a first semiconductor interposer 100) comprises a first semiconductor substrate 110; and a horizontal plane including a bonding interface between the first polymer bonding layer 49 (which may comprise a proximal polymer bonding layer 149) and the second polymer bonding layer 59 (which may comprise a fan-out polymer bonding layer 359) is more distal from a horizontal plane including a proximal horizontal surface of the first semiconductor substrate 110 than interfaces between the solder material portions 48 (which may comprise first solder material portions 148) and the second metallic bump structures 54 (which may comprise fan-out metallic bump structures 354) are from the horizontal plane including the proximal horizontal surface of the first semiconductor substrate 110.

In one embodiment, the first semiconductor substrate 110 embeds the first through-substrate via structures 120, and is laterally surrounded by a molding compound frame (such as a molding compound interposer frame 335); and the second package structure 920 (such as a fan-out semiconductor package 290) comprises a semiconductor die 200 including field effect transistors (which are a subset of the semiconductor devices 220) therein.

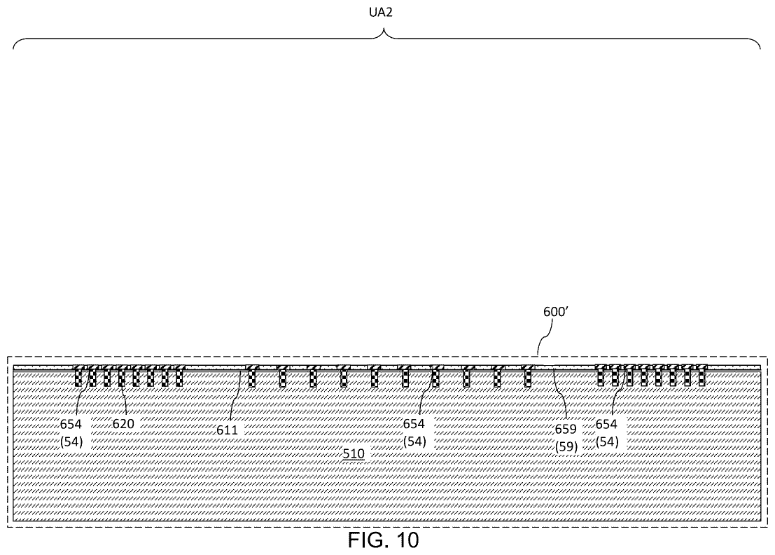

Referring to FIG. 10, an in-process semiconductor interposer 600′ is illustrated, which may be provided within a semiconductor wafer including an array of in-process semiconductor interposers 600′. As used herein, an “in-process” element refers to an element that is modified in material composition and/or shape in at least one subsequent processing step. The illustrated region of the wafer corresponds to a unit area UA2 of repetition in which as single in-process semiconductor interposer 600′ is provided. Each in-process semiconductor interposer 600′ may be processed into a second semiconductor interposer during subsequent processing steps.

An interposer semiconductor substrate 510 is illustrated, which is a portion of the semiconductor wafer that is located within the unit area UA2 of repetition. The unit area UA2 of repetition in the semiconductor wafer is less than unit area UA1 of repetition for forming the die-interposer assembly 300 shown in FIGS. 1-4 and 6-8. A planar insulating layer 611 may be formed on the top surface of the interposer semiconductor substrate 510. Via cavities having a depth in a range from 2 microns to 40 microns may be formed through the planar insulating layer 611 and into an upper portion of the interposer semiconductor substrate 510. A combination of an insulating spacer (not shown) and a second through-substrate via (TSV) structure 620 may be formed in each via cavity by performing material deposition processes and a planarization process (such as a chemical mechanical polishing process).

Metallic bump structures, which are herein referred to as silicon-interposer metallic bump structures 654, may be formed in the planar insulating layer 611. According to an aspect of the present disclosure, the silicon-interposer metallic bump structures 654 comprise pillar portions having an identical structure as the pillar portions of the second metallic bump structures 54 described with reference to FIGS. 5E-5G. Thus, the silicon-interposer metallic bump structures 654 are formed as the second metallic bump structures 54 for the purpose of a subsequent bonding process, and may have an identical configuration, or may have a substantively identical configuration (in embodiments in which via portions are not formed), as the second metallic bump structures 54 described with reference to FIGS. 5E-5G. In this embodiment, the second TSV structures 620 function as the second metallic interconnection structures 928.

Further, a second polymer bonding layer 59 may be formed around the second metallic bump structures 54 (which may comprise the silicon-interposer metallic bump structures 654) as described with reference to FIGS. 5F and 5G. In this embodiment, the second polymer bonding layer 59 is herein referred to as a silicon-interposer polymer bonding layer 659.

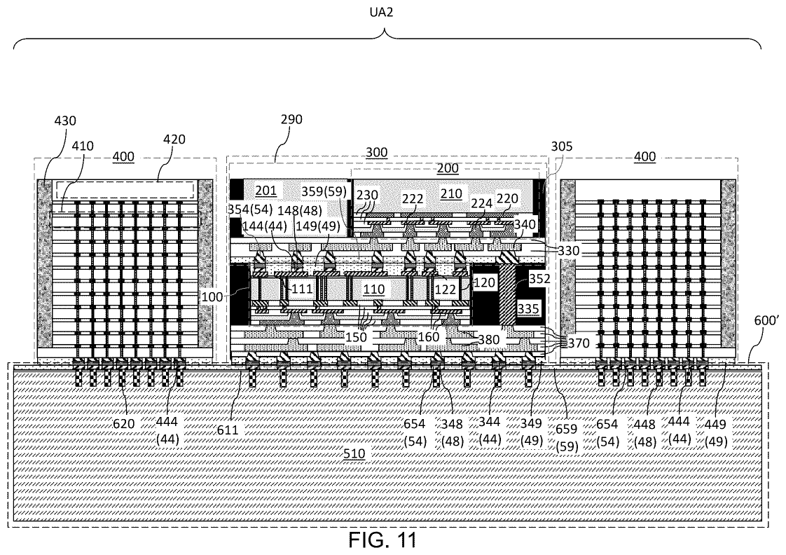

Referring to FIG. 11, a hybrid bonding process including a combination of a solder bonding and a polymer-to-polymer bonding may be performed in the same manner as described with reference to FIG. 5I. In this embodiment, the die-interposer assembly 300 illustrated in FIG. 9 functions as a first package structure 910, and the in-process semiconductor interposer 600′ functions as a second package structure 920. The first TSV structures 120, the proximal redistribution wiring interconnects 122, the first distal redistribution wiring interconnects 160, and the second distal redistribution wiring interconnects 380 function as the first metallic interconnection structures 918 within the first package structure 910. The second TSV structures 620 function as the second metallic interconnection structures 928 in the second package structure 920. The distal metallic bump structures 344 in the die-interposer assembly 300 function as the first metallic bump structures 44. The second solder material portions 348 function as the solder material portions 48. The silicon-interposer metallic bump structures 654 of the in-process semiconductor interposer 600′ function as the second metallic bump structures 54. The distal polymer bonding layer 349 functions as the first polymer bonding layer 49. The silicon-interposer polymer bonding layer 659 functions as the second polymer bonding layer 59.

Referring collectively to the processing steps described with reference to FIGS. 5A-5I and FIGS. 7-11, a first package structure 910 (which may comprise a die-interposer assembly 300) may be provided. The first package structure 910 comprises first metallic interconnection structures 918 (such as first TSV structures 120, proximal redistribution wiring interconnects 122, first distal redistribution wiring interconnects 160, and optionally second distal redistribution wiring interconnects 380) (such as first TSV structures 120, proximal redistribution wiring interconnects 122, first distal redistribution wiring interconnects 160, and optionally second distal redistribution wiring interconnects 380), first metallic bump structures 44 (which may comprise distal metallic bump structures 344) electrically connected to the first metallic interconnection structures 918 (such as first TSV structures 120, proximal redistribution wiring interconnects 122, first distal redistribution wiring interconnects 160, and optionally second distal redistribution wiring interconnects 380), and a first polymer bonding layer 49 (which may comprise a distal polymer bonding layer 349) laterally surrounding the first metallic bump structures 44 (which may comprise distal metallic bump structures 344). Solder material portions 48 (such as the second solder material portions 348) may be formed on the first metallic bump structures 44.

In one embodiment, the first polymer bonding layer 49 (which may comprise a distal polymer bonding layer 349) may be provided by forming the solder material portions 48 on the first metallic bump structures 44, by forming an first polymer material layer 49′ having a planar top surface over first metallic bump structures 44 (which may comprise distal metallic bump structures 344) and solder material portions 48 (which may comprise second solder material portions 348), and by vertically recessing the first polymer material layer 49′ until top surfaces of the solder material portions 48 are exposed. The first polymer bonding layer 49 comprises a remaining portion of the first polymer material layer 49′. The solder material portions 48 (which may comprise second solder material portions 348) may be vertically recessed selective to the first polymer bonding layer 49 (which may comprise a distal polymer bonding layer 349). In one embodiment, physically exposed surfaces of the solder material portions 48 (which may comprise second solder material portions 348) are vertically recessed relative to a physically exposed surface of the first polymer bonding layer 49 (which may comprise a distal polymer bonding layer 349) prior to performing the bonding process.

A second package structure 920 (which may comprise an in-process semiconductor interposer 600′) may be provided. The second package structure 920 comprises second metallic interconnection structures 928 (which may comprise second TSV structures 620), second metallic bump structures 54 (which may comprise silicon-interposer metallic bump structures 654) electrically connected to the second metallic interconnection structures 928 (which may comprise second TSV structures 620), and a second polymer bonding layer 59 (which may comprise a silicon-interposer polymer bonding layer 659) laterally surrounding the second metallic bump structures 54 (which may comprise silicon-interposer metallic bump structures 654). In one embodiment, an second polymer material layer 59′ having a planar top surface may be formed over the second metallic bump structures 54 (which may comprise silicon-interposer metallic bump structures 654). A top surface of the second polymer material layer 59′ may be vertically recessed below a horizontal plane including top surfaces of the second metallic bump structures 54 (which may comprise silicon-interposer metallic bump structures 654). The second polymer bonding layer 59 (which may comprise a silicon-interposer polymer bonding layer 659) is formed.

During the hybrid bonding process, the second metallic bump structures 54 are brought into contact with the solder material portions 48. The assembly of the first package structure 910 and the second package structure 920 may be heated to, or above, the solder reflow temperature to induce reflow of the solder material portions 48, and to induce bonding between the solder material portions 48 and the second metallic bump structures 54. The elevated temperature of the reflow process may be in a range from 250 degrees to 300 degrees Celsius, and the duration of the reflow process may be in a range from 10 seconds to 60 seconds. Subsequently, while the solder material portions 48 are at, or below, the reflow temperature, the assembly of the first package structure 910 and the second package structure 920 may be annealed at an elevated temperature to induce polymer-to-polymer bonding between the first polymer bonding layer 49 and the second polymer bonding layer 59. The elevated temperature may be in a range from 200 degrees Celsius to 300 degrees Celsius. The duration of the anneal process may be in a range from 30 minutes to 3 hours, although lesser and greater durations may also be used.

Further, additional semiconductor dies or additional semiconductor packages may be bonded to the in-process semiconductor interposer 600′ concurrently with, prior to, or after, bonding the die-interposer assembly 300 to the in-process semiconductor interposer 600′. For example, at least one memory die 400 such as at least one high bandwidth memory (HBM) memory die may be provided. Each HBM memory die may comprise a vertical stack of memory layers 410 and a base layer 420 containing a logic circuit for controlling operation of the memory arrays in the memory layers 410. A molding compound frame 430 may laterally surround the vertical stack of memory layers 410 and the base layer 420. Generally, first metallic bump structures 44, solder material portions 48, and a first polymer bonding layer 49 may be provided on each memory die 400. The first metallic bump structures 44 that are formed on the at least one memory die 400 are herein referred to as memory-die metallic bump structures 444. The solder material portions 48 provided on the memory-die metallic bump structures 444 are herein referred to as third solder material portions 448. The first polymer bonding layer(s) 44 that are formed on the at least one memory die 400 is/are herein referred to as (a) memory-die polymer bonding layer(s) 449. Each memory die 400 may be bonded to the in-process semiconductor interposer 600′ using the processing steps described with reference to FIGS. 5A-5I.

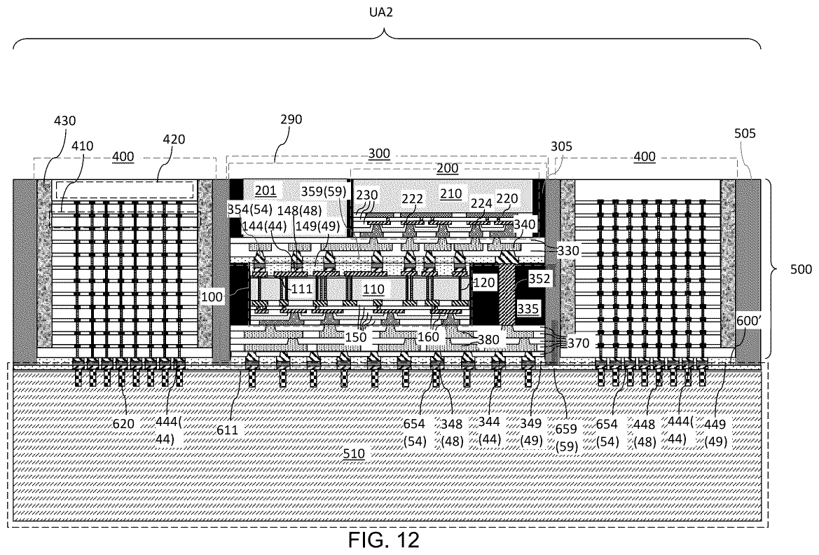

Referring to FIG. 12, an encapsulant, such as a molding compound (MC) material, may be applied to the gaps between the die-interposer assemblies 300 and the memory dies 400 that are bonded to the array of in-process semiconductor interposers 600′. The encapsulant may comprise any material that may be used for the molding compound die frames 305 or molding compound interposer frames 335 as described above. A planarization process may be performed to remove portions of the MC material that overlies the horizontal plane including the topmost surfaces of the semiconductor dies 200 and the memory dies 400. The top surfaces of the semiconductor dies 200 and the dummy dies 201 may be coplanar with the top surface of a remaining portion of the MC material. The remaining portion of the MC material comprises a molding compound matrix. Each portion of the molding compound matrix located within the unit area UA2 constitutes a molding compound die frame that laterally surrounds a plurality of semiconductor dies, and is herein referred to as a molding compound multi-die frame 505. The combination of the array of in-process semiconductor interposer 600′, the die-interposer assemblies 300, the memory dies 400, and the molding compound matrix constitutes a reconstituted wafer. The reconstituted wafer may comprise a two-dimensional array of reconstituted dies. Each reconstituted die may be located within a respective unit area UA2, and may comprise an in-process semiconductor interposer 600′, a die-interposer assembly 300, at least one memory dies 400, and a molding compound multi-die frame 505. The illustrated portion of the exemplary structure corresponds to a unit area UA2, i.e., a region including a single repetition unit within the reconstituted wafer.

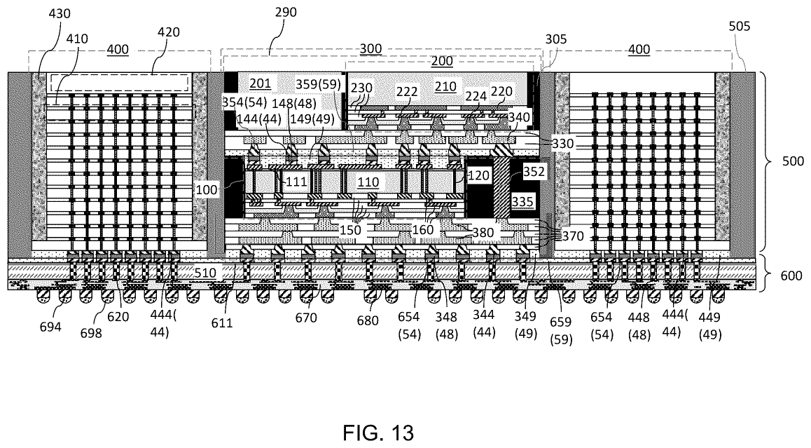

Referring to FIG. 13, the reconstituted wafer may be thinned from the backside. Specifically, the backside portion of the semiconductor wafer including the array of interposer semiconductor substrates 510 may be removed by performing a thinning process. The thinning process may use a grinding process, a polishing process, an anisotropic etch process, and/or an isotropic etch process. The thinning process may be continued until backside surfaces of the second TSV structures 620 are exposed. Subsequently, a backside redistribution structure may be formed on the physically exposed backside surfaces of the semiconductor wafer and the second TSV structures 620. The backside redistribution structure may comprise backside redistribution dielectric layer 670 and backside redistribution wiring interconnects 680.

Backside bump structures 694 may be formed on the last level of the backside redistribution wiring interconnects 680. The backside bump structures 694 may comprise microbump structures or C4 bonding pads. Solder material portions 698 may be formed on the backside bump structures 694. Upon thinning of the semiconductor wafer and upon formation of the backside redistribution structure, the backside bump structures 694, and the solder material portions 698, the in-process semiconductor interposers 600′ are converted into semiconductor interposers, which are herein referred to second semiconductor interposers 600.

The reconstituted wafer may be diced along dicing channels. Each diced portion of the reconstituted wafer comprises a third-stage composite package, which includes an assembly of a second semiconductor interposer 600, a die-interposer assembly 300, at least one memory die 400, and a molding compound multi-die frame 505.

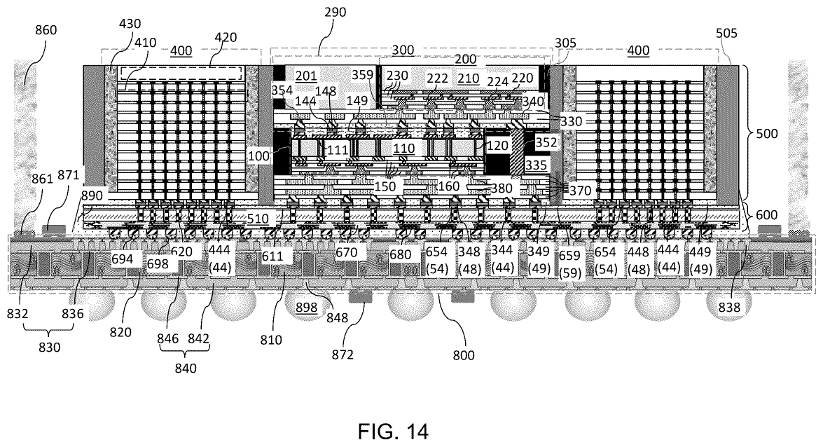

Referring to FIG. 14, a first assembly of a third-stage composite package and a packaging substrate 800 is illustrated. The packaging substrate 800 may be a cored packaging substrate including a core substrate 810, or a coreless packaging substrate that does not include a package core. Alternatively, the packaging substrate 800 may include a system-on-integrated packaging substrate (SoIS) including redistribution layers. dielectric interlayers, and/or at least one embedded interposer (such as a silicon interposer). Such a system-integrated packaging substrate may include layer-to-layer interconnections using solder material portions, microbumps, underfill material portions (such as molded underfill material portions), and/or an adhesion film. While the present disclosure is described using a cored packaging substrate, it is understood that the scope of the present disclosure is not limited by any particular type of substrate package. For example, an SoIS may be used in lieu of a cored packaging substrate. In embodiments in which SoIS is used, the core substrate 810 may include a glass epoxy plate including an array of through-plate holes. An array of through-core via structures 820 including a metallic material may be provided in the through-plate holes. Each through-core via structure 820 may, or may not, include a cylindrical hollow therein. Optionally, dielectric liners (not illustrated) may be used to electrically isolate the through-core via structures 820 from the core substrate 810.

The packaging substrate 800 may include board-side surface laminar circuit (SLC) 840 and a chip-side surface laminar circuit (SLC) 830. The board-side SLC 840 may include board-side insulating layers 842 embedding board-side wiring interconnects 846. The chip-side SLC 830 may include chip-side insulating layers 832 embedding chip-side wiring interconnects 836. The board-side insulating layers 842 and the chip-side insulating layers 832 may include a photosensitive epoxy material that may be lithographically patterned and subsequently cured. The board-side wiring interconnects 846 and the chip-side wiring interconnects 836 may include copper that may be deposited by electroplating within patterns in the board-side insulating layers 842 or the chip-side insulating layers 832.

In one embodiment, the chip-side surface laminar circuit 830 comprises chip-side wiring interconnects 836 that are connected to an array of substrate bonding pads 838. The array of substrate bonding pads 838 may be configured to allow bonding through C4 solder balls. The board-side surface laminar circuit 840 comprises board-side wiring interconnects 846 that are connected to an array of board-side bonding pads 848. The array of board-side bonding pads 848 is configured to allow bonding through solder joints having a greater dimension than the C4 solder balls. While the present disclosure is described using an embodiment in which the packaging substrate 800 includes a chip-side surface laminar circuit 830 and a board-side surface laminar circuit 840, embodiments are expressly contemplated herein in which one of the chip-side surface laminar circuit 830 and the board-side surface laminar circuit 840 is omitted, or is replaced with an array of bonding structures such as microbumps. In an illustrative example, the chip-side surface laminar circuit 830 may be replaced with an array of microbumps or any other array of bonding structures.

The third-stage composite package including the assembly of a second semiconductor interposer 600, a die-interposer assembly 300, at least one memory die 400, and a molding compound multi-die frame 505 may be bonded to the packaging substrate 800 through solder material portions 698. In this embodiment, each solder material portion 698 may be bonded to a respective pair of a backside bump structure 694 and a substrate bonding pads 838. Optionally, integrated passive devices (871, 872) may be bonded to the chip-side surface laminar circuit 830 and/or to the board-side surface laminar circuit 840. For example, chip-side integrated passive devices 871 may be bonded to the chip-side surface laminar circuit 830, and board-side integrated passive devices 872 may be bonded to the board-side surface laminar circuit 840. Optionally, a stabilizer structure 860 such as a stabilization ring or a stabilization cap structure may be attached to the packaging substrate 800 using an adhesive layer 861.

A underfill material portion 890 may be formed within each unit area between the second semiconductor interposer 600 and the packaging substrate 800. The underfill material portion 890 may be formed by injecting the die-side underfill material around a respective array of backside bump structures 694 and solder material portions 698 in a respective unit area. Any known underfill material application method may be used, which may be, for example, the capillary underfill method, the molded underfill method, or the printed underfill method.

Within each unit area, a underfill material portion 890 may laterally surround, and contact, a respective set of the solder material portions 790 within the unit area. The die-side underfill material portion 792 may be formed around, and contact, the backside bump structures 694 and solder material portions 698 in the unit area.

Solder balls 898 may be attached to the underside of the packaging substrate 800 for coupling to a printed circuit board (not shown)

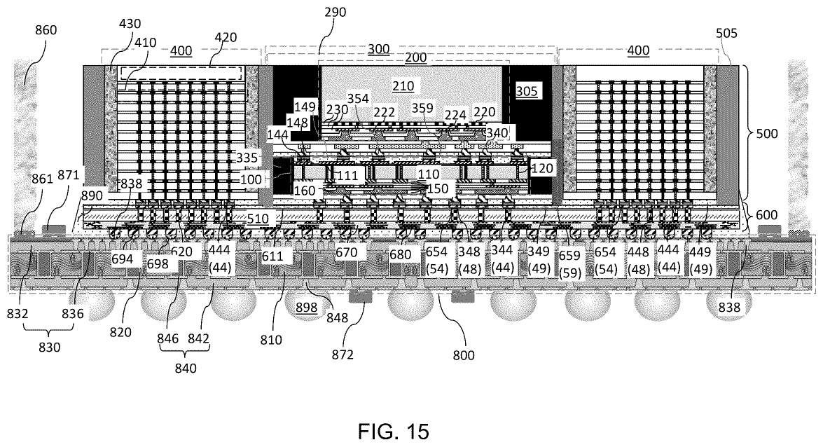

Referring to FIG. 15, a second assembly of a third-stage composite package and a packaging substrate 800 is illustrated. The second assembly may be derived from the first assembly illustrated in FIG. 15 by modifying the die-interposer assembly 300. In this embodiment, the fan-out semiconductor package 290 may be formed without any dummy die 201 therein. Alternatively or additionally, the TIV structures 352 may not be used during formation of the die-interposer assembly 300. Alternatively or additionally, the second distal redistribution wiring interconnects 380 and the second distal redistribution dielectric layers 370 may be omitted.

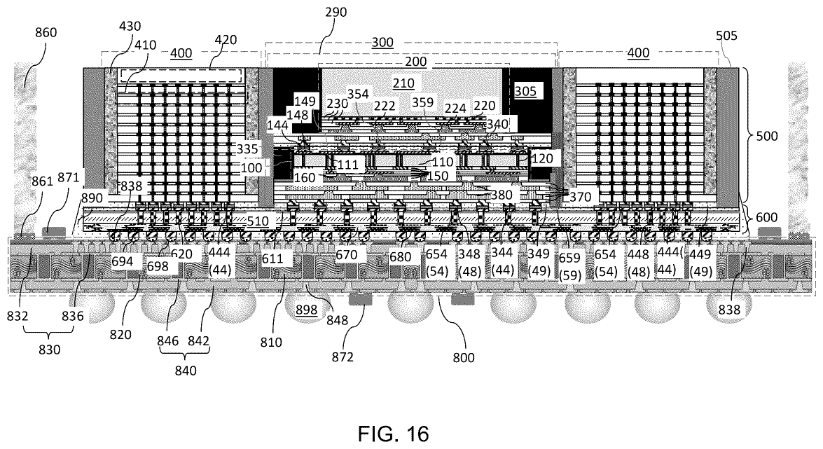

Referring to FIG. 16, a third assembly of a third-stage composite package and a packaging substrate 800 is illustrated. The third assembly may be derived from the first assembly illustrated in FIG. 15 by modifying the die-interposer assembly 300. In this embodiment, the fan-out semiconductor package 290 may be formed without any dummy die 201 therein. Alternatively or additionally, the TIV structures 352 may not be used during formation of the die-interposer assembly 300.

Referring collectively to FIGS. 13-16 and according to various embodiments of the present disclosure, a bonded assembly is provided, which comprises: a first package structure 910 (which may comprise a die-interposer assembly 300) comprising first metallic interconnection structures 918 (such as first TSV structures 120, proximal redistribution wiring interconnects 122, first distal redistribution wiring interconnects 160, and optionally second distal redistribution wiring interconnects 380) (such as first TSV structures 120, proximal redistribution wiring interconnects 122, first distal redistribution wiring interconnects 160, and optionally second distal redistribution wiring interconnects 380), first metallic bump structures 44 (which may comprise distal metallic bump structures 344) electrically connected to the first metallic interconnection structures 918 (such as first TSV structures 120, proximal redistribution wiring interconnects 122, first distal redistribution wiring interconnects 160, and optionally second distal redistribution wiring interconnects 380), and a first polymer bonding layer 49 (which may comprise a distal polymer bonding layer 349) laterally surrounding the first metallic bump structures 44 (which may comprise distal metallic bump structures 344); a second package structure 920 (which may comprise a second semiconductor interposer 600) comprising second metallic interconnection structures 928 (which may comprise second TSV structures 620), second metallic bump structures 54 (which may comprise silicon-interposer metallic bump structures 654) electrically connected to the second metallic interconnection structures 928 (which may comprise second TSV structures 620), and a second polymer bonding layer 59 (which may comprise a silicon-interposer polymer bonding layer 659) laterally surrounding the second metallic bump structures 54 (which may comprise silicon-interposer metallic bump structures 654); and solder material portions 48 (which may comprise second solder material portions 348) located between the first metallic bump structures 44 (which may comprise distal metallic bump structures 344) and the second metallic bump structures 54 (which may comprise silicon-interposer metallic bump structures 654). Each of the solder material portions 48 (which may comprise second solder material portions 348) is bonded to a respective one of the first metallic bump structures 44 (which may comprise distal metallic bump structures 344) and a respective one of the second metallic bump structures 54 (which may comprise silicon-interposer metallic bump structures 654); and the second polymer bonding layer 59 (which may comprise a silicon-interposer polymer bonding layer 659) is bonded to the first polymer bonding layer 49 (which may comprise a distal polymer bonding layer 349) through polymer-to-polymer bonding.

In one embodiment, the first package structure 910 (which may comprise a die-interposer assembly 300) comprises a first semiconductor substrate 110 including through-substrate via structures 120 therethrough, wherein the first metallic interconnection structures 918 (such as first TSV structures 120, proximal redistribution wiring interconnects 122, first distal redistribution wiring interconnects 160, and optionally second distal redistribution wiring interconnects 380) comprise the through-substrate via structures 120. In one embodiment, the first package structure 910 (which may comprise a die-interposer assembly 300) is laterally surrounded by a molding compound frame (such as a molding compound interposer frame 335) that laterally surrounds the first semiconductor substrate 110.

In one embodiment, the first metallic interconnection structures 918 (such as first TSV structures 120, proximal redistribution wiring interconnects 122, first distal redistribution wiring interconnects 160, and optionally second distal redistribution wiring interconnects 380) comprise first redistribution wiring interconnects (such as first distal redistribution wiring interconnects 160) that are embedded in first redistribution dielectric layers (such as first distal redistribution dielectric layers 150); and the first redistribution dielectric layers (such as first distal redistribution dielectric layers 150) are laterally surrounded by the molding compound frame (such as a molding compound interposer frame 335).

In one embodiment, the first metallic interconnection structures 918 (such as first TSV structures 120, proximal redistribution wiring interconnects 122, first distal redistribution wiring interconnects 160, and optionally second distal redistribution wiring interconnects 380) comprise second redistribution wiring interconnects (such as second distal redistribution wiring interconnects 380) that are formed within second redistribution dielectric layers (such as second distal redistribution dielectric layers 370); and the second redistribution dielectric layers (such as second distal redistribution dielectric layers 370) comprise a horizontal surface that contacts the molding compound frame (such as a molding compound interposer frame 335) and comprise sidewalls that are vertically coincident with outer sidewalls of the molding compound frame (such as a molding compound interposer frame 335).

In one embodiment, the second package structure 920 comprises a second semiconductor interposer 600 comprising an additional semiconductor substrate (such as an interposer semiconductor substrate 510) and additional through-substrate via structures (such as the second TSV structures 620) and having a greater lateral extent than the first semiconductor substrate 110 of the first package structure 910 (which may comprise a die-interposer assembly 300).

In one embodiment, a horizontal bonding interface between the second polymer bonding layer 59 (which may comprise a silicon-interposer polymer bonding layer 659) and the first polymer bonding layer 49 (which may comprise a distal polymer bonding layer 349) is more distal from a horizontal plane including a proximal horizontal surface of the first semiconductor substrate 110 of the first package structure 910 (which may comprise a die-interposer assembly 300) than interfaces between the solder material portions 48 (which may comprise second solder material portions 348) and the second metallic bump structures 54 (which may comprise silicon-interposer metallic bump structures 654) are from the proximal horizontal surface of the first semiconductor substrate 110 of the first package structure 910 (which may comprise a die-interposer assembly 300).

In one embodiment, each of the solder material portions 48 (which may comprise second solder material portions 348) is laterally surrounded by, and is contacted by, the first polymer bonding layer 49 (which may comprise a distal polymer bonding layer 349). In one embodiment, the second polymer bonding layer 59 (which may comprise a silicon-interposer polymer bonding layer 659) is spaced from, and does not contact, the solder material portions 48 (which may comprise second solder material portions 348). In one embodiment, the first polymer bonding layer 49 (which may comprise a distal polymer bonding layer 349) is spaced from, and does not contact, the second package structure 920 (which may comprise a second semiconductor interposer 600); and the second polymer bonding layer 59 (which may comprise a silicon-interposer polymer bonding layer 659) is spaced from, and does not contact, the first package structure 910 (which may comprise a die-interposer assembly 300).

According to another aspect of the present disclosure, a bonded assembly is provided, which comprises: a first package structure 910 (which may comprise a die-interposer assembly 300) comprising first metallic interconnection structures 918 (such as first TSV structures 120, proximal redistribution wiring interconnects 122, first distal redistribution wiring interconnects 160, and optionally second distal redistribution wiring interconnects 380), first metallic bump structures 44 (which may comprise distal metallic bump structures 344) electrically connected to the first metallic interconnection structures 918 (such as first TSV structures 120, proximal redistribution wiring interconnects 122, first distal redistribution wiring interconnects 160, and optionally second distal redistribution wiring interconnects 380), and a first polymer bonding layer 49 (which may comprise a distal polymer bonding layer 349) laterally surrounding the first metallic bump structures 44 (which may comprise distal metallic bump structures 344); a second package structure 920 (which may comprise a second semiconductor interposer 600) comprising second metallic interconnection structures 928 (which may comprise second TSV structures 620), second metallic bump structures 54 (which may comprise silicon-interposer metallic bump structures 654) electrically connected to the second metallic interconnection structures 928 (which may comprise second TSV structures 620), and a second polymer bonding layer 59 (which may comprise a silicon-interposer polymer bonding layer 659) laterally surrounding the second metallic bump structures 54 (which may comprise silicon-interposer metallic bump structures 654); and solder material portions 48 (which may comprise second solder material portions 348) located between the first metallic bump structures 44 (which may comprise distal metallic bump structures 344) and the second metallic bump structures 54 (which may comprise silicon-interposer metallic bump structures 654). Each of the solder material portions 48 (which may comprise second solder material portions 348) is bonded to a respective one of the first metallic bump structures 44 (which may comprise distal metallic bump structures 344) and a respective one of the second metallic bump structures 54 (which may comprise silicon-interposer metallic bump structures 654), is laterally surrounded by the first polymer bonding layer 49 (which may comprise a distal polymer bonding layer 349), and is not in direct with the second polymer bonding layer 59 (which may comprise a silicon-interposer polymer bonding layer 659); and the first polymer bonding layer 49 (which may comprise a distal polymer bonding layer 349) is spaced from the second package structure 920 (which may comprise a second semiconductor interposer 600) by the second polymer bonding layer 59 (which may comprise a silicon-interposer polymer bonding layer 659).

In one embodiment, the second polymer bonding layer 59 (which may comprise a silicon-interposer polymer bonding layer 659) is bonded to the first polymer bonding layer 49 (which may comprise a distal polymer bonding layer 349) by polymer-to-polymer bonding. In one embodiment, the first package structure 910 (which may comprise a die-interposer assembly 300) comprises a first semiconductor substrate 110; and a horizontal plane including a bonding interface between the first polymer bonding layer 49 (which may comprise a distal polymer bonding layer 349) and the second polymer bonding layer 59 (which may comprise a silicon-interposer polymer bonding layer 659) is more distal from a horizontal plane including a proximal horizontal surface of the first semiconductor substrate 110 than interfaces between the solder material portions 48 (which may comprise second solder material portions 348) and the second metallic bump structures 54 (which may comprise silicon-interposer metallic bump structures 654) are from the horizontal plane including the proximal horizontal surface of the first semiconductor substrate 110.

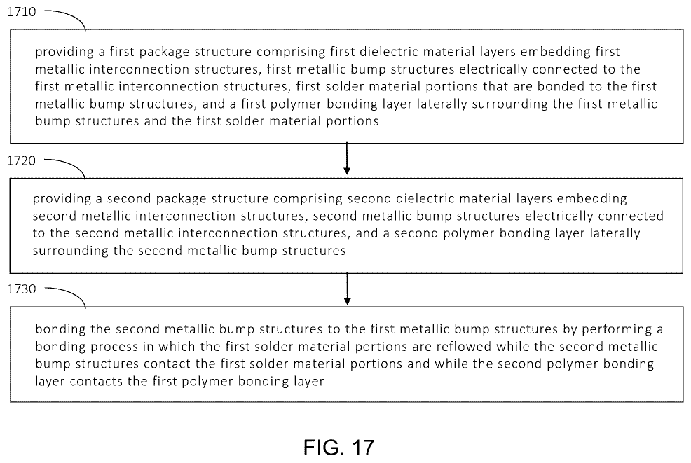

FIG. 17 is a flowchart illustrating steps for forming a bonded assembly according to an embodiment of the present disclosure.

Referring to step 1710 and FIGS. 4, 5A-5D, and 6-9, a first package structure 910 (which may comprise a first semiconductor interposer 100 or as a die-interposer assembly 300) is provided, which comprises first metallic interconnection structures 918 (such as first TSV structures 120, proximal redistribution wiring interconnects 122, first distal redistribution wiring interconnects 160, and optionally second distal redistribution wiring interconnects 380), first metallic bump structures 44 (which may comprise proximal metallic bump structures 144 or as distal metallic bump structures 344) electrically connected to the first metallic interconnection structures 918 (such as first TSV structures 120, proximal redistribution wiring interconnects 122, first distal redistribution wiring interconnects 160, and optionally second distal redistribution wiring interconnects 380), solder material portions 48 (which may comprise first solder material portions 148 or second solder material portions 348) that are bonded to the first metallic bump structures 44 (which may comprise proximal metallic bump structures 144 or as distal metallic bump structures 344), and a first polymer bonding layer 49 (which may comprise a proximal polymer bonding layer 149 or as a distal polymer bonding layer 349) laterally surrounding the first metallic bump structures 44 (which may comprise proximal metallic bump structures 144 or as distal metallic bump structures 344) and the solder material portions 48 (which may comprise first solder material portions 148 or second solder material portions 348).

Referring to step 1720 and FIGS. 1-3, 5E-5G, and 10, a second package structure 920 (such as a fan-out semiconductor package 290 or a in-process semiconductor interposer 600′) comprising second metallic interconnection structures 928 (which may comprise metal interconnect structures 222, die-side bonding pads 224, fan-out redistribution wiring interconnects 340 or second TSV structures 620), second metallic bump structures 54 (which may comprise fan-out metallic bump structures 354 or silicon-interposer metallic bump structures 654) electrically connected to the second metallic interconnection structures 928 (which may comprise metal interconnect structures 222, die-side bonding pads 224, fan-out redistribution wiring interconnects 340 or second TSV structures 620), and a second polymer bonding layer 59 (which may comprise a fan-out polymer bonding layer 359 or as a silicon-interposer polymer bonding layer 659) laterally surrounding the second metallic bump structures 54 (which may comprise fan-out metallic bump structures 354 or silicon-interposer metallic bump structures 654).

Referring to step 1730 and FIGS. 4, 5H, 5I, and 11-16, the second metallic bump structures 54 (which may comprise fan-out metallic bump structures 354 or silicon-interposer metallic bump structures 654) may be bonded to the first metallic bump structures 44 (which may comprise proximal metallic bump structures 144 or as distal metallic bump structures 344) by performing a bonding process in which the solder material portions 48 (which may comprise first solder material portions 148 or second solder material portions 348) are reflowed while the second metallic bump structures 54 (which may comprise fan-out metallic bump structures 354 or silicon-interposer metallic bump structures 654) contact the solder material portions 48 (which may comprise first solder material portions 148 or second solder material portions 348) and while the second polymer bonding layer 59 (which may comprise a fan-out polymer bonding layer 359 or as a silicon-interposer polymer bonding layer 659) contacts the first polymer bonding layer 49 (which may comprise a proximal polymer bonding layer 149 or as a distal polymer bonding layer 349).

The various embodiments of the present disclosure may be used to provide hybrid bonding structures in which a first package structure 910 and a second package structure 910 are bonded to each other by solder bonding and polymer-to-polymer bonding. The hybrid bonding of the present disclosure provides enhanced bonding strength between the first package structure 910 and the second package structure 920 compared to a bonded assembly using solder bonding only. The strength of the polymer-to-polymer bonding may be enhanced by selecting a pair of polymer materials that may provide enhanced bonding strength, for example, through formation of a two-component adhesive material such as an epoxy.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonded assembly comprising:
a first package structure comprising:
first metallic interconnection structures;
first metallic bump structures electrically connected to the first metallic interconnection structures; and
a first polymer bonding layer laterally surrounding the first metallic bump structures;
a second package structure comprising:
second metallic interconnection structures;
second metallic bump structures electrically connected to the second metallic interconnection structures; and
a second polymer bonding layer laterally surrounding the second metallic bump structures; and
solder material portions located between the first metallic bump structures and the second metallic bump structures, wherein:
each of the solder material portions is bonded to a respective one of the first metallic bump structures and a respective one of the second metallic bump structures; and
the second polymer bonding layer is bonded to the first polymer bonding layer through polymer-to-polymer bonding.

2. The bonded assembly of claim 1, wherein the first package structure comprises a semiconductor substrate including through-substrate via structures therethrough, wherein the first metallic interconnection structures comprise the through-substrate via structures.

3. The bonded assembly of claim 2, wherein the first package structure is laterally surrounded by a molding compound frame that laterally surrounds the semiconductor substrate.

4. The bonded assembly of claim 3, wherein:
the first metallic interconnection structures comprise first redistribution wiring interconnects that are formed within first redistribution dielectric layers; and
the first redistribution dielectric layers are laterally surrounded by the molding compound frame.

5. The bonded assembly of claim 4, wherein:
the first metallic interconnection structures comprise second redistribution wiring interconnects that are formed within second redistribution dielectric layers; and
the second redistribution dielectric layers comprise a horizontal surface that contacts the molding compound frame and comprise sidewalls that are vertically coincident with outer sidewalls of the molding compound frame.

6. The bonded assembly of claim 2, wherein the second package structure comprises:
an additional semiconductor substrate; and
field effect transistors located on the additional semiconductor substrate, wherein the second metallic interconnection structures comprise metal interconnect structures that are electrically connected to the field effect transistors.

7. The bonded assembly of claim 2, wherein the second package structure comprises a semiconductor substrate comprising an additional semiconductor substrate and additional through-substrate via structures and having a greater lateral extent than the semiconductor substrate of the first package structure.

8. The bonded assembly of claim 2, wherein a horizontal bonding interface between the second polymer bonding layer and the first polymer bonding layer is more distal from a horizontal plane including a proximal horizontal surface of the semiconductor substrate of the first package structure than interfaces between the solder material portions and the second metallic bump structures are from the proximal horizontal surface of the semiconductor substrate of the first package structure.

9. The bonded assembly of claim 1, wherein each of the solder material portions is laterally surrounded by, and is contacted by, the first polymer bonding layer.

10. The bonded assembly of claim 1, wherein the second polymer bonding layer is spaced from, and does not contact, the solder material portions.

11. The bonded assembly of claim 1, wherein:
the first polymer bonding layer is spaced from, and does not contact, the second package structure; and
the second polymer bonding layer is spaced from, and does not contact, the first package structure.

12. A bonded assembly comprising:
a first package structure comprising:
first metallic interconnection structures;
first metallic bump structures electrically connected to the first metallic interconnection structures; and
a first polymer bonding layer laterally surrounding the first metallic bump structures;
a second package structure comprising:
second metallic interconnection structures;
second metallic bump structures electrically connected to the second metallic interconnection structures; and
a second polymer bonding layer laterally surrounding the second metallic bump structures; and
solder material portions located between the first metallic bump structures and the second metallic bump structures, wherein:
each of the solder material portions is bonded to a respective one of the first metallic bump structures and a respective one of the second metallic bump structures, is laterally surrounded by the first polymer bonding layer, and is not in direct with the second polymer bonding layer; and
the first polymer bonding layer is spaced from the second package structure by the second polymer bonding layer.

13. The bonded assembly of claim 12, wherein the second polymer bonding layer is bonded to the first polymer bonding layer by polymer-to-polymer bonding.

14. The bonded assembly of claim 13, wherein:
the first package structure comprises a semiconductor substrate; and
a horizontal plane including a bonding interface between the first polymer bonding layer and the second polymer bonding layer is more distal from a horizontal plane including a proximal horizontal surface of the semiconductor substrate than interfaces between the solder material portions and the second metallic bump structures are from the horizontal plane including the proximal horizontal surface of the semiconductor substrate.

15. The bonded assembly of claim 14, wherein:
the semiconductor substrate has formed therein through-substrate via structures, and is laterally surrounded by a molding compound frame; and
the second package structure comprises a semiconductor die including field effect transistors therein.

16. A method of forming a bonded assembly, the method comprising:
providing a first package structure comprising:
first metallic interconnection structures;
first metallic bump structures electrically connected to the first metallic interconnection structures;
solder material portions that are bonded to the first metallic bump structures; and
a first polymer bonding layer laterally surrounding the first metallic bump structures and the solder material portions;
providing a second package structure comprising:
second metallic interconnection structures;
second metallic bump structures electrically connected to the second metallic interconnection structures; and
a second polymer bonding layer laterally surrounding the second metallic bump structures; and
bonding the second metallic bump structures to the first metallic bump structures by performing a bonding process in which the solder material portions are reflowed while the second metallic bump structures contact the solder material portions and while the second polymer bonding layer contacts the first polymer bonding layer.

17. The method of claim 16, wherein the second polymer bonding layer is bonded to the first polymer bonding layer while the solder material portions reflow.

18. The method of claim 16, wherein physically exposed surfaces of the solder material portions are vertically recessed relative to a physically exposed surface of the first polymer bonding layer prior to performing the bonding process.

19. The method of claim 16, wherein providing the first package structure comprises:
forming a first polymer material layer having a planar top surface over the first metallic bump structures;
removing an upper portion of the first polymer material layer until top surfaces of the solder material portions are exposed, whereby the first polymer bonding layer is formed; and
vertically recessing the solder material portions selective to the first polymer bonding layer.

20. The method of claim 16, wherein providing the second package structure comprises:
forming an second polymer material layer having a planar top surface over the second metallic bump structures; and
vertically recessing a top surface of the second polymer material layer below a horizontal plane including top surfaces of the second metallic bump structures, whereby the second polymer bonding layer is formed.
